(19) United States
(12) Patent Application Publication
(10) Pub. No.: US 2026/0347235 A1
(43) Pub. Date: Nov. 5, 2026

(54) SILICA GLASS SUBSTRATE, GLASS SUBSTRATE, AND METALLIZED SUBSTRATE

(71) Applicant: AGC Inc., Tokyo (JP)

(72) Inventor: Mami IKUTAME, Tokyo (JP)

(73) Assignee: AGC Inc., Tokyo (JP)

(21) Appl. No.: 19/711,594

(22) Filed: Jun. 17, 2026

Related U.S. Application Data
(63) Continuation of application No. PCT/JP2024/044478, filed on Dec. 16, 2024.

(30) Foreign Application Priority Data
Dec. 20, 2023 (JP) 2023-214759

(51) Int. Cl. C03C 3/06; C03C 17/09

(52) U.S. Cl. CPC C03C 3/06; C03C 17/09; C03C 2201/26; C03C 2201/32; C03C 2201/42; C03C 2201/50; C03C 2201/54; C03C 2217/25; C03C 2218/15

(57) ABSTRACT

A silica glass substrate has a root mean square height Rq of 1 nm or more and 300 nm or less on a substrate surface, and a thickness of 10 μm or more and 2 mm or less. A glass substrate has a root mean square height Rq of 1 nm or more and 300 nm or less on a substrate surface, and a thickness of 10 μm or more and 2 mm or less, and contains 60 mol % or more and less than 100 mol % of SiO₂ as represented by mol % based on oxides.

### CROSS-REFERENCE TO RELATED APPLICATIONS

This is a bypass continuation of International Application No. PCT/JP2024/044478 filed on Dec. 16, 2024, and claims priority from Japanese Patent Application No. 2023-214759 filed on Dec. 20, 2023, the entire content of which is incorporated herein by reference.

### TECHNICAL FIELD

The present invention relates to a silica glass substrate, a glass substrate, and a metallized substrate.

### BACKGROUND ART

In an electronic device such as a communication device such as a mobile phone, a smartphone, a personal digital assistant, or a Wi-Fi device, a surface acoustic wave (SAW) device, a radar component, or an antenna component, a signal frequency has been increased in order to increase a communication capacity, a communication speed, or the like. As a circuit board for use in such an electronic device for high-frequency applications, for example, a metallized substrate formed by metallizing an insulating substrate such as a resin substrate or a glass ceramic substrate is used.

The insulating substrate for use in a high-frequency device is required to have a reduced transmission loss based on a dielectric loss, a conductor loss, and the like in order to ensure properties such as a quality and an intensity of a high-frequency signal. Among these insulating substrates, the resin substrate has low rigidity due to properties thereof. Therefore, in the case where the rigidity (strength) is required for a semiconductor package product, it is difficult to apply the resin substrate. It is difficult to improve surface smoothness of the glass ceramic substrate, and accordingly, there is a disadvantage that the conductor loss caused by a conductor formed on the substrate surface is likely to increase.

On the other hand, since a glass substrate has high rigidity, it is likely to reduce a size and a thickness of the package, it is excellent in surface smoothness, and it is likely to increase the size of the substrate itself.

However, there has been a problem in that the metallized layer formed on the surface of the glass substrate tends to peel off due to poor adhesion between the glass substrate and the metal film.

Regarding the problem related to the adhesion between the glass and the metal film, Non-Patent Literature 1 reports, in order to form a metal layer having high adhesion on the surface of the glass, a method of adsorbing a palladium catalyst by a reaction between a zinc oxide film and palladium chloride and reducing the palladium catalyst with a reducing agent, and a method of reducing metal ions by irradiating zinc oxide with light using optical semiconductor properties of zinc oxide. Patent Literature 1 discloses a chemical plating method for ensuring adhesion between a base material and a metal film.

### CITATION LIST

Patent Literature 1: JP2011-195896A
Non-Patent Literature 1: Electronics Packaging Technology (VOL. 11, No. 6, P32, 1995)

### SUMMARY OF INVENTION

However, in the above-described methods, a special device is required, and there is a problem that productivity is low since steps are complicated and take time. Therefore, there is a demand for a metallized glass substrate having high adhesion between the glass substrate and the metal film without requiring a special metallization step.

In addition, a thickness of the substrate is important to reduce the transmission loss in a high-frequency band. In general, in order to prevent noise, the thickness of the substrate is designed to be a value smaller than λ/2, where λ is the wavelength of the high-frequency wave. For example, when a device using a silica glass substrate or a glass substrate is to be designed at a high-frequency of 10 GHz, since λ/2 is 7.7 mm, a substrate having a thickness smaller than this is required, and the thinner the substrate, the smaller the transmission loss due to the noise suppression effect.

Therefore, an object of the present invention is to provide an insulating substrate that does not require a special metallization step, in which the formed metallized layer is less likely to peel off even when the substrate surface is metallized, and that has low high-frequency transmission loss.

The present inventors have focused on a silica glass substrate and a glass substrate having a small dielectric loss as an insulating substrate to be metallized. It has been found that, by setting the surface roughness Rq of the silica glass substrate or the glass substrate to a specific range, the formed metallized layer is less likely to peel off even when the substrate surface is metallized, and by setting the thickness to 2 mm or less, an insulating substrate having low high-frequency transmission loss can be provided, and the present invention has been completed.

That is, one embodiment of the present invention relates to a silica glass substrate or a glass substrate having a specific composition which have a root mean square height Rq of 1 nm or more and 300 nm or less on a substrate surface and having a thickness of 10 μm or more and 2 mm or less.

Another embodiment of the present invention relates to a metallized substrate in which a metallized layer is provided on a surface of the silica glass substrate or the glass substrate.

According to one embodiment of the present invention, it is possible to provide a silica glass substrate and a glass substrate as insulating substrates that do not require a special metallization step, in which the formed metallized layer is less likely to peel off even when the substrate surface is metallized, and in which high-frequency transmission loss is reduced.

### BRIEF DESCRIPTION OF DRAWINGS

FIG. 1 is a schematic cross-sectional view of a silica glass substrate according to one embodiment of the present invention.

FIG. 2 is a schematic cross-sectional view of a metallized substrate according to one embodiment of the present invention.

FIG. 3 is a Raman spectrum of the silica glass substrate according to the embodiment of the present invention.

### DESCRIPTION OF EMBODIMENTS

Hereinafter, the present invention is described in detail, but the present invention is not limited to the following embodiment and can be freely modified and implemented without departing from the gist of the present invention. In addition, “to” that is used to express a numerical range includes the numerical values before and after it as the upper limit value and the lower limit value of the range, respectively. Embodiments described in the drawings are schematically for the purpose of clearly illustrating the present invention, and do not necessarily accurately represent a size or a scale of an actual apparatus.

In the present specification, mass % and wt % have the same meaning, and ppm by mass and ppm by weight have the same meaning.

### <Silica Glass Substrate>

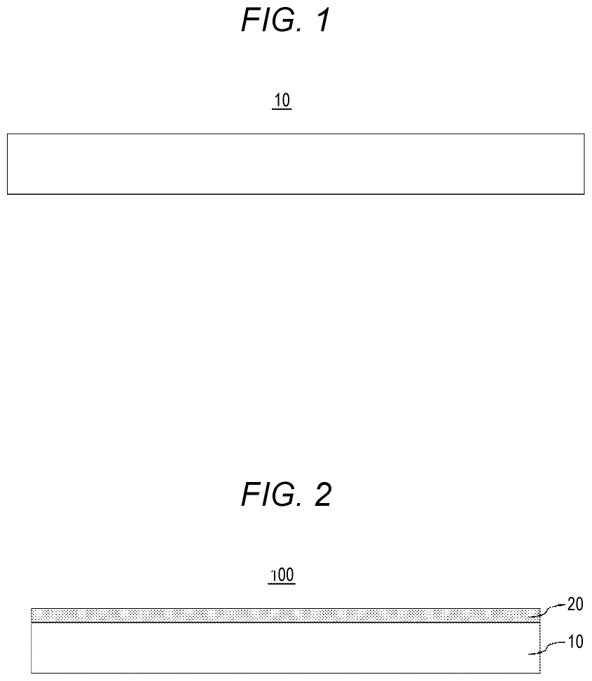

The silica glass substrate according to one embodiment of the present invention (hereinafter, also simply referred to as a silica glass substrate according to the present embodiment) has a root mean square height Rq of 1 nm or more and 300 nm or less on a substrate surface, and a thickness of 10 μm or more and 2 mm or less. FIG. 1 shows a schematic cross-sectional view of a silica glass substrate 10 according to the present embodiment.

### (Rq)

In the silica glass substrate according to the present embodiment, it is important that the root mean square height Rq on the substrate surface is 1 nm or more and 300 nm or less. When the Rq is 1 nm or more and 300 nm or less, adhesion between the substrate and a metallized layer formed on the substrate surface is sufficient, and the metallized layer is less likely to peel off from the substrate surface.

In the silica glass substrate according to the present embodiment, the root mean square height Rq on the substrate surface is 1 nm or more, preferably 5 nm or more, more preferably 10 nm or more, particularly preferably 20 nm or more, and is 300 nm or less, preferably 200 nm or less, more preferably 150 nm or less, particularly preferably 100 nm or less.

Here, the root mean square height Rq on the substrate surface is defined in JIS B 0601 (2013), represents the root mean square at a reference length, and means a standard deviation of the surface roughness of the substrate. The root mean square height Rq on the substrate surface can be measured using, for example, SURFCOM 1400D manufactured by TOKYO SEIMITSU CO., LTD.

In the silica glass substrate according to the present embodiment, in order to set the Rq on the substrate surface to 1 nm or more and 300 nm or less, for example, as to be described later, a method of producing a silica glass substrate by a sintering method is exemplified. Since surface properties are easily controlled by producing the silica glass substrate by the sintering method, the Rq can be easily adjusted to the above range. A method of polishing a synthetic quartz glass or a molten quartz glass to obtain any surface roughness is also exemplified.

### (Thickness)

It is important that the silica glass substrate according to the present embodiment has a thickness of 10 μm or more and 2 mm or less. When the thickness is 10 μm or more and 2 mm or less, high-frequency transmission loss is reduced.

The thickness of the silica glass substrate according to the present embodiment is 10 μm or more, preferably 50 μm or more, more preferably 100 μm or more, particularly preferably 150 μm or more, and is 2 mm or less, preferably 1 mm or less, more preferably 0.5 mm or less, particularly preferably 0.2 mm or less.

### (Df)

The silica glass substrate according to the present embodiment preferably has a dielectric loss tangent (Df) of 5.0×10⁻⁵ to 1.0×10⁻³ at 10 GHz. When the Df is within the above range, high-frequency transmission loss can be kept small. The Df is more preferably 5.0×10⁻⁴ or less, still more preferably 1.0×10⁻⁴ or less, and may be, for example, 5.0×10⁻⁵ or more.

The Df can be measured by a dielectric resonator method.

### (Defects)

The silica glass substrate according to the present embodiment preferably has 500,000 or less defects having an average diameter of 1 μm or more and 100 μm or less per cm². Here, the “defect” refers to a heterogeneous phase other than the glass, such as crystals or bubbles observed when measured using an optical microscope. The average diameter means an average of diameters (average diameter), each diameter connecting two points on the outer periphery of a defect extracted by image analysis software based on the color and shape of a pattern and passing through the center of gravity, in an optical microscope image in which a glass portion is selected as a background by the image analysis software. When the number of defects is 500,000 or less, it is possible to suppress Rq from exceeding 300 nm.

In the silica glass substrate according to the present embodiment, the number of defects having an average diameter of 1 μm or more and 100 μm or less is more preferably 300,000 or less, still more preferably 100,000 or less, particularly preferably 10,000 or less per cm², and is, for example, 1,000 or more per cm².

In the silica glass substrate according to the present embodiment, the number of defects having an average diameter of 5 μm or more and 100 μm or less is more preferably 5,000 or less, still more preferably 3,000 or less, particularly preferably 2,000 or less per cm², and is, for example, 50 or more per cm².

In the silica glass substrate according to the present embodiment, the number of defects having an average diameter of 1 μm or more and 5 μm or less is more preferably 30,000 or less, still more preferably 15,000 or less, particularly preferably 10,000 or less per cm², and is, for example, 100 or more per cm².

### (H₂O Concentration)

In the silica glass substrate according to the present embodiment, an H₂O concentration converted from β-OH in the glass is preferably less than 100 ppm by mass. When the H₂O concentration is less than 100 ppm by mass, the amount of moisture in the glass is sufficiently small, so that high-frequency transmission loss can be further reduced. The H₂O concentration in the silica glass substrate according to the present embodiment is preferably less than 100 ppm by mass, more preferably 50 ppm by mass or less, still more preferably 20 ppm by mass or less, particularly preferably 10 ppm by mass or less, and is, for example, 0.5 ppm by mass or more.

The H₂O concentration in the silica glass substrate according to the present embodiment is obtained according to the following equation based on a spectrum measured by FT-IR (Fourier transform infrared spectrophotometer).
H₂O concentration=((|A1−A2|/t))*M/(10εp)*10000 [ppm by mass]
A1: average intensity at a reference wave number of 3900 cm⁻¹ to 4000 cm⁻¹
A2: maximum intensity at a hydroxy group absorption wavenumber of 3400 cm⁻¹ to 3800 cm⁻¹
t: thickness (mm)
ε: molar absorption coefficient of β-OH=8.6 (L/mol/mm)
ρ: specific gravity=2.2 (g/cm³)
M: H₂O molecular weight=18 (g/mol)

### (Composition)

In the present embodiment, the silica glass substrate means a substrate made of glass, also referred to as quartz glass, substantially consisting only of SiO₂. The glass substantially consisting only of SiO₂ means a glass that may contain, for example, Na, K, Ca, C, Zr, Ti, Al, Mg, Fe, Zn, and the like in addition to SiO₂, and each content thereof is on the order of ppm by mass.

### (Total Content of Na, K, and Ca)

In the silica glass substrate according to the present embodiment, the total content of Na, K, and Ca is preferably 0.1 ppm by mass or more and 50 ppm by mass or less. When the total content of Na, K, and Ca is 0.1 ppm by mass or more and 50 ppm by mass or less, microcrystals can be prevented, so that the surface roughness Rq can be controlled to 300 nm or less, and high-frequency transmission loss can be further reduced. The total content of Na, K, and Ca is more preferably 20 ppm by mass or less, still more preferably 10 ppm by mass or less, particularly preferably 5 ppm by mass or less, and is more preferably 0.3 ppm by mass or more, particularly preferably 0.5 ppm by mass or more.

### (Content of C)

The silica glass substrate according to the present embodiment preferably has a content of C of 5 ppm by mass or less. When the content of C is 5 ppm by mass or less, the amount of impurities is reduced, and the microcrystals can be prevented, so that the surface roughness Rq can be controlled to 300 nm or less, and high-frequency transmission loss can be further reduced. The content of C is more preferably 4 ppm by mass or less, still more preferably 3 ppm by mass or less, and may be, for example, 0.5 ppm by mass or more.

In order to set the content of C in the silica glass substrate according to the present embodiment within the above range, for example, a method in which a resin component is not used as a raw material may be used.

### (Content of Zr)

The silica glass substrate according to the present embodiment preferably has a content of Zr of 50 ppm by mass or less. When the content of Zr is 50 ppm by mass or less, the amount of impurities is reduced, and the microcrystals can be prevented, so that the surface roughness Rq can be controlled to 300 nm or less, and high-frequency transmission loss can be further reduced. The content of Zr is more preferably 10 ppm by mass or less, still more preferably 1 ppm by mass or less, particularly preferably 0.2 ppm by mass or less, and may be, for example, 0.1 ppm by mass or more.

In order to set the content of Zr in the silica glass substrate according to the present embodiment within the above range, for example, a method in which a raw material not containing Zr is selected may be used.

### (Content of Ti)

The silica glass substrate according to the present embodiment preferably has a content of Ti of 50 ppm by mass or less. When the content of Ti is 50 ppm by mass or less, the amount of impurities is reduced, and the microcrystals can be prevented, so that the surface roughness Rq can be controlled to 300 nm or less, and high-frequency transmission loss can be further reduced. The content of Ti is more preferably 30 ppm by mass or less, still more preferably 10 ppm by mass or less, particularly preferably 3 ppm by mass or less, and may be, for example, 0.1 ppm by mass or more.

In order to set the content of Ti in the silica glass substrate according to the present embodiment within the above range, for example, a method in which a raw material not containing Ti is selected may be used.

### (Content of Al)

The silica glass substrate according to the present embodiment preferably has a content of Al of 50 ppm by mass or less. When the content of Al is 50 ppm by mass or less, the microcrystals can be prevented, so that the surface roughness Rq can be controlled to 300 nm or less, and high-frequency transmission loss can be further reduced. The content of Al is more preferably 30 ppm by mass or less, still more preferably 10 ppm by mass or less, particularly preferably 3 ppm by mass or less, and may be, for example, 0.1 ppm by mass or more.

In order to set the content of Al in the silica glass substrate according to the present embodiment within the above range, for example, a method in which a raw material not containing Al is selected may be used.

The silica glass substrate according to the present embodiment preferably satisfies at least one of the following conditions: the total content of Na, K, and Ca: 0.1 ppm by mass or more and 50 ppm by mass or less; the content of C: 5 ppm by mass or less; the content of Zr: 50 ppm by mass or less; the content of Ti: 50 ppm by mass or less; and the content of Al: 50 ppm by mass or less. It more preferably satisfies at least two of these conditions, still more preferably at least three of these conditions, even more preferably at least four of these conditions, and particularly preferably all five of these conditions.

In addition to the above, it is more preferable that the H₂O concentration converted from β-OH be less than 100 ppm by mass.

### (Etching Rate (Relative Value))

The silica glass substrate according to the present embodiment preferably has an etching rate of more than 1 when being immersed in an aqueous solution containing 8 wt % of HF and 7 wt % of HNO₃, in terms of a relative value when an etching rate of a synthetic quartz glass is 1. When the etching rate is more than 1, it is possible to increase the etching rate when adjusting a size of a hole by etching after drilling with a laser.

The etching rate of the silica glass substrate according to the present embodiment is more preferably 1.1 or more, still more preferably 1.2 or more, and particularly preferably 1.3 or more, in terms of the relative value when the etching rate of the synthetic quartz glass is 1. Here, the synthetic quartz glass means a synthetic quartz glass prepared by a vapor-phase axial deposition method (VAD method).

In order to set the etching rate in the silica glass substrate according to the present embodiment to the above range, the D2/PH is set to 0.10 or more, or the D1/PH is set to 0.40 or more.

The etching rate of the silica glass substrate according to the present embodiment can be calculated, for example, by immersing a silica glass substrate masked with Kapton tape in an aqueous solution containing 8 wt % HF and 7 wt % HNO₃ for 5 hours, removing the mask, and calculating the etching rate from step height measurement results obtained using a stylus-type surface profilometer (Dektak 150, manufactured by Bruker). Specifically, since the masked portion is not etched, the etching amount can be calculated by measuring step height at a boundary between the masked portion and the unmasked portion.

### (Raman Spectrum)

In the silica glass substrate according to the present embodiment, the ratio (D2/PH) of the intensity of a D2 peak derived from a three-membered ring structure at 605 cm⁻¹ to the height (PH) of a combined peak of three Si—O fundamental vibrations at 370 cm⁻¹, 390 cm⁻¹, and 450 cm⁻¹ in a Raman spectrum is preferably 0.10 or more. When the D2/PH is 0.10 or more, it is possible to increase the etching rate when adjusting a size of a hole by etching after drilling with a laser.

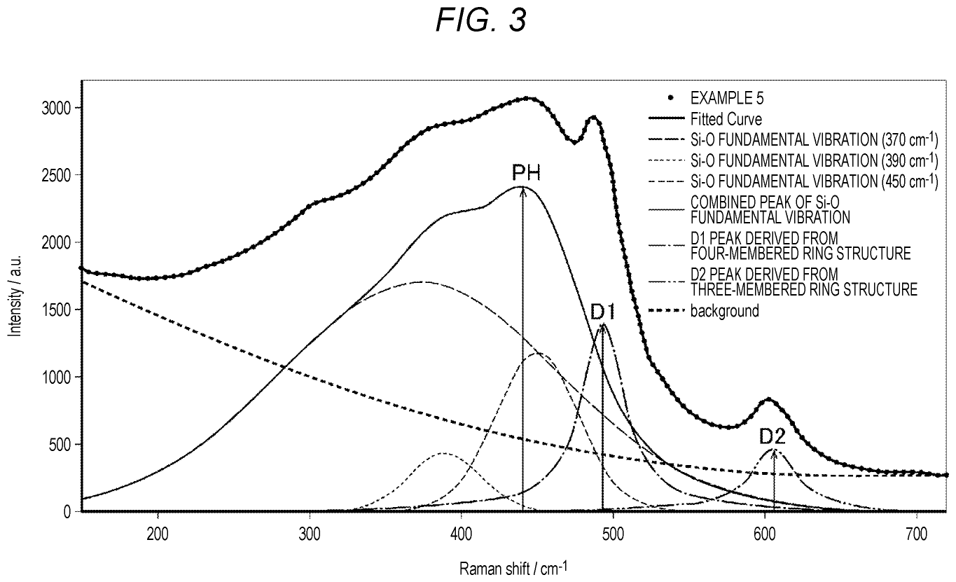

In a Raman spectrum shown in FIG. 3, the peak marked by D2 is a peak derived from a three-membered ring structure, and the position indicated by D2 corresponds to the peak intensity (D2). The peak indicated by the solid line is the combined peak of the Si—O fundamental vibrations, and the position indicated by PH is the peak height (PH).

The D2/PH is preferably 0.10 or more, more preferably 0.15 or more, still more preferably 0.17 or more, particularly preferably 0.18 or more, and may be, for example, 0.25 or less.

In order to set the D2/PH within the above range, for example, a method of producing silica glass having a low fictive temperature by rapid cooling or the like may be used.

In the silica glass substrate according to the present embodiment, a ratio (D1/PH) of the intensity of a D1 peak derived from a four-membered ring structure at 490 cm⁻¹ to the height (PH) of a combined peak of three Si—O fundamental vibrations at 370 cm⁻¹, 390 cm⁻¹, and 450 cm⁻¹ in a Raman spectrum is preferably 0.40 or more. When the D1/PH is 0.40 or more, the etching rate can be increased.

As shown in FIG. 3, the peak marked by D1 is a peak derived from a four-membered ring structure, and the position indicated by D1 corresponds to the peak intensity (D1). The peak indicated by the solid line is the combined peak of the Si—O fundamental vibrations, and the position indicated by PH is the peak height (PH).

The D1/PH is preferably 0.40 or more, more preferably 0.50 or more, still more preferably 0.55 or more, even more preferably 0.57 or more, and may be, for example, 0.7 or less.

In order to set the D1/PH within the above range, for example, a method of producing silica glass having a low fictive temperature by rapid cooling or the like may be used.

In the silica glass substrate according to the present embodiment, it is more preferable that the D2/PH be 0.10 or more and the D1/PH be 0.40 or more.

The Raman spectrum is obtained by using a microscopic laser Raman spectrometer. The measurement region is a cylindrical region located 5 μm below the surface of the silica glass substrate according to the present embodiment and having a diameter of about 3 μm and a length of about 3 μm.

### <Glass Substrate>

The glass substrate according to one embodiment of the present invention (hereinafter, also simply referred to as a glass substrate according to the present embodiment) has a root mean square height Rq of 1 nm or more and 300 nm or less on a substrate surface, and a thickness of 10 μm or more and 2 mm or less. FIG. 1 shows a schematic cross-sectional view of a silica glass substrate 10 according to the present embodiment, and the same applies to a case where a glass substrate is used instead of the silica glass substrate.

### (Rq)

In the glass substrate according to the present embodiment, it is important that the root mean square height Rq on the substrate surface is 1 nm or more and 300 nm or less. When the Rq is 1 nm or more and 300 nm or less, adhesion between the substrate and a metallized layer formed on the substrate surface is sufficient, and the metallized layer is less likely to peel off from the substrate surface.

In the glass substrate according to the present embodiment, the root mean square height Rq on the substrate surface is 1 nm or more, preferably 5 nm or more, more preferably 10 nm or more, particularly preferably 20 nm or more, and is 300 nm or less, preferably 200 nm or less, more preferably 150 nm or less, particularly preferably 100 nm or less.

Here, the root mean square height Rq on the substrate surface is defined in JIS B 0601 (2013), represents the root mean square at a reference length, and means a standard deviation of the surface roughness of the substrate. The root mean square height Rq on the substrate surface can be measured using, for example, SURFCOM 1400D manufactured by TOKYO SEIMITSU CO., LTD.

In the glass substrate according to the present embodiment, in order to set the Rq on the substrate surface to 1 nm or more and 300 nm or less, for example, as to be described later, a method of producing a glass substrate by a sintering method is exemplified. Since surface properties are easily controlled by producing the glass substrate by the sintering method, the Rq can be easily adjusted to the above range.

A method of polishing a plate glass produced by a melting method to obtain any surface roughness Rq is also exemplified. As a method for producing the plate glass, examples include methods in which a float process, a roll method, a drawing method, a down-draw method, an overflow fusion down-draw method, an up-draw method, a Fourcault method, or the like is employed in the melting process and the subsequent hot-forming process.

### (Thickness)

It is important that the glass substrate according to the present embodiment has a thickness of 10 μm or more and 2 mm or less. When the thickness is 10 μm or more and 2 mm or less, high-frequency transmission loss is reduced.

The thickness of the glass substrate according to the present embodiment is 10 μm or more, preferably 50 μm or more, more preferably 100 μm or more, particularly preferably 150 μm or more, and is 2 mm or less, preferably 1 mm or less, more preferably 0.5 mm or less, particularly preferably 0.2 mm or less.

### (Df)

The glass substrate according to the present embodiment preferably has a dielectric loss tangent (Df) of 5.0×10⁻⁵ to 1.0×10⁻³ at 10 GHz. When the Df is within the above range, high-frequency transmission loss can be kept small. The Df is more preferably 4.0×10⁻³ or less, still more preferably 3.0×10⁻³ or less, and may be, for example, 5.0×10⁻⁵ or more.

The Df can be measured by a dielectric resonator method.

### (Defects)

The glass substrate according to the present embodiment preferably has 500,000 or less defects having an average diameter of 1 μm or more and 100 μm or less per cm². Here, the “defect” refers to a heterogeneous phase other than the glass, such as crystals or bubbles observed when measured using an optical microscope. The average diameter means an average of diameters (average diameter), each diameter connecting two points on the outer periphery of a defect extracted by image analysis software based on the color and shape of a pattern and passing through the center of gravity, in an optical microscope image in which a glass portion is selected as a background by the image analysis software. When the number of defects is 500,000 or less, it is possible to prevent the Rq from being more than 300 nm.

In the glass substrate according to the present embodiment, the number of defects having an average diameter of 1 μm or more and 100 μm or less is more preferably 300,000 or less, still more preferably 100,000 or less, particularly preferably 10,000 or less per cm², and is, for example, 1,000 or more per cm².

In the glass substrate according to the present embodiment, the number of defects having an average diameter of 5 μm or more and 100 μm or less is more preferably 5,000 or less, still more preferably 3,000 or less, particularly preferably 2,000 or less per cm², and is, for example, 50 or more per cm².

In the glass substrate according to the present embodiment, the number of defects having an average diameter of 1 μm or more and 5 μm or less is more preferably 30,000 or less, still more preferably 15,000 or less, particularly preferably 10,000 or less per cm², and is, for example, 100 or more per cm².

### (Composition)

The glass substrate in the present embodiment contains 60 mol % or more and less than 100 mol % of SiO₂ as represented by mol % based on oxides. Here, the content of SiO₂ is 60 mol % or more, preferably 72 mol % or more, and more preferably 75 mol % or more, from the viewpoint of obtaining a low loss substrate. The content is less than 100 mol %, preferably 90 mol % or less, more preferably 89 mol % or less, still more preferably 88 mol % or less, and even more preferably 85 mol % or less, from the viewpoint of increasing a linear expansion coefficient and improving reliability of a device.

(Content of B₂O₃)

The glass substrate in the present embodiment preferably contains 10 mol % to 35 mol % of B₂O₃ as represented by mol % based on oxides. Here, the content of B₂O₃ is preferably 10 mol % or more, more preferably 12 mol % or more, and still more preferably 15 mol % or more, from the viewpoint of increasing the linear expansion coefficient and improving the reliability of the device. The content is preferably 35 mol % or less, more preferably 30 mol % or less, and still more preferably 25 mol % or less, from the viewpoint of weather resistance.

(Contents of P₂O₅, GeO₂, CaO, MgO, BaO, Li₂O, Na₂O, K₂O, SnO₂, ZnO, and TiO₂)

The glass substrate in the present embodiment preferably further contains at least one of P₂O₅, GeO₂, CaO, MgO, BaO, Li₂O, Na₂O, K₂O, SnO₂, ZnO, and TiO₂ as represented by mol % based on oxides, and in this case, the total content thereof is more preferably 1 mol % to 15 mol %. Here, the total content is preferably 1 mol % or more, and more preferably 3 mol % or more, from the viewpoint of lowering a melting point of the glass and improving sinterability. The total content is preferably 15 mol % or less, and more preferably 10 mol % or less, from the viewpoint of reducing a dielectric loss.

The content of each component is not particularly limited as long as the total content is 1 mol % to 15 mol %, and is, for example, preferably 1 mol % or more, more preferably 2 mol % or more, and still more preferably 3 mol % or more. The content of each component is preferably 15 mol % or less, more preferably 12 mol % or less, and still more preferably 10 mol % or less.

The glass substrate in the present embodiment preferably, in addition to SiO₂: 60 mol % or more and less than 100 mol %, as represented by mol % based on oxides, satisfies at least one of the following conditions: B₂O₃: 10 mol % to 35 mol %; and the total of P₂O₅, GeO₂, CaO, MgO, BaO, Li₂O, Na₂O, K₂O, SnO₂, ZnO, and TiO₂: 1 mol % to 15 mol %, and more preferably satisfies both conditions.

### (Total Content of Na, K, and Ca)

In the glass substrate according to the present embodiment, the total content of Na, K, and Ca is preferably 0.1 ppm by mass or more and 50 ppm by mass or less. When the total content of Na, K, and Ca is 0.1 ppm by mass or more and 50 ppm by mass or less, microcrystals can be prevented, so that the surface roughness Rq can be controlled to 300 nm or less, and high-frequency transmission loss can be further reduced. The total content of Na, K, and Ca is more preferably 20 ppm by mass or less, still more preferably 10 ppm by mass or less, particularly preferably 5 ppm by mass or less, and is more preferably 0.3 ppm by mass or more, particularly preferably 0.5 ppm by mass or more.

### (Content of C)

The glass substrate according to the present embodiment preferably has a content of C of 5 ppm by mass or less. When the content of C is 5 ppm by mass or less, the amount of impurities is reduced, and the microcrystals can be prevented, so that the surface roughness Rq can be controlled to 300 nm or less, and high-frequency transmission loss can be further reduced. The content of C is more preferably 4 ppm by mass or less, still more preferably 3 ppm by mass or less, and may be, for example, 0.5 ppm by mass or more.

In order to set the content of C in the glass substrate according to the present embodiment within the above range, for example, a method in which a resin component is not used as a raw material may be used.

### (Content of Zr)

The glass substrate according to the present embodiment preferably has a content of Zr of 50 ppm by mass or less. When the content of Zr is 50 ppm by mass or less, the amount of impurities is reduced, and the microcrystals can be prevented, so that the surface roughness Rq can be controlled to 300 nm or less, and high-frequency transmission loss can be further reduced. The content of Zr is more preferably 10 ppm by mass or less, still more preferably 1 ppm by mass or less, particularly preferably 0.2 ppm by mass or less, and may be, for example, 0.1 ppm by mass or more.

In order to set the content of Zr in the glass substrate according to the present embodiment within the above range, for example, a method in which a raw material not containing Zr is selected may be used.

### (Content of Ti)

The glass substrate according to the present embodiment preferably has a content of Ti of 50 ppm by mass or less. When the content of Ti is 50 ppm by mass or less, the amount of impurities is reduced, and the microcrystals can be prevented, so that the surface roughness Rq can be controlled to 300 nm or less, and high-frequency transmission loss can be further reduced. The content of Ti is more preferably 30 ppm by mass or less, still more preferably 10 ppm by mass or less, particularly preferably 3 ppm by mass or less, and may be, for example, 0.1 ppm by mass or more.

In order to set the content of Ti in the glass substrate according to the present embodiment within the above range, for example, a method in which a raw material not containing Ti is selected may be used.

### (Content of Al)

The glass substrate according to the present embodiment preferably has a content of Al of 50 ppm by mass or less. When the content of Al is 50 ppm by mass or less, the microcrystals can be prevented, so that the surface roughness Rq can be controlled to 300 nm or less, and high-frequency transmission loss can be further reduced. The content of Al is more preferably 30 ppm by mass or less, still more preferably 10 ppm by mass or less, particularly preferably 3 ppm by mass or less, and may be, for example, 0.1 ppm by mass or more.

In order to set the content of Al in the glass substrate according to the present embodiment within the above range, for example, a method in which a raw material not containing Al is selected may be used.

The glass substrate according to the present embodiment preferably satisfies at least one of the following conditions: the total content of Na, K, and Ca: 0.1 ppm by mass or more and 50 ppm by mass or less; the content of C: 5 ppm by mass or less; the content of Zr: 50 ppm by mass or less; the content of Ti: 50 ppm by mass or less; and the content of Al: 50 ppm by mass or less. It more preferably satisfies at least two of these conditions, still more preferably at least three of these conditions, even more preferably at least four of these conditions, and particularly preferably all five of these conditions.

### (Etching Rate (Relative Value))

The glass substrate according to the present embodiment preferably has an etching rate of more than 1 when being immersed in an aqueous solution containing 8 wt % of HF and 7 wt % of HNO₃, in terms of a relative value when an etching rate of a synthetic quartz glass is 1. When the etching rate is more than 1, it is possible to increase the etching rate when adjusting a size of a hole by etching after drilling with a laser.

The etching rate of the glass substrate according to the present embodiment is more preferably 1.1 or more, still more preferably 1.2 or more, and particularly preferably 1.3 or more, in terms of the relative value when the etching rate of the synthetic quartz glass is 1. Here, the synthetic quartz glass means a synthetic quartz glass prepared by the VAD method.

The etching rate of the glass substrate according to the present embodiment can be calculated, for example, by immersing a glass substrate masked with Kapton tape in an aqueous solution containing 8 wt % HF and 7 wt % HNO₃ for 5 hours, removing the mask, and calculating the etching rate from step height measurement results obtained using a stylus-type surface profilometer (Dektak 150, manufactured by Bruker). Specifically, since the masked portion is not etched, the etching amount can be calculated by measuring step height at a boundary between the masked portion and the unmasked portion.

### <Method for Producing Silica Glass Substrate>

A method for producing the silica glass substrate according to the present embodiment is not particularly limited, and the silica glass substrate is preferably obtained by sintering a green sheet containing silica. According to this production method, a substrate having a thickness of 2 mm or less can be directly obtained without cutting and polishing, and any surface roughness Rq can be realized without post-processing, so that there is an advantage that a silica glass substrate in which metallization is less likely to peel off with a low loss can be easily prepared.

Hereinafter, a method for producing a silica glass substrate according to the present embodiment by a sintering method is exemplarily described, but the silica glass substrate according to the present embodiment is not limited to one obtained by this production method.

### Preparation of Slurry Composition

As an example of the method for producing a silica glass substrate according to the present embodiment, first, a slurry composition is prepared. The slurry composition can be obtained by mixing a silica powder, a binder, and an organic solvent. In addition, as to be described later, a dispersant, a plasticizer, an antifoaming agent, and the like can also be mixed. The mixing method is not particularly limited, and a known method can be used.

### (Silica Powder)

The kind of the silica powder is not particularly limited, and examples thereof include silica sand, a quartz powder, a cristobalite powder, an amorphous silica powder, and a spherical silica powder. The silica powder may be used alone or in combination of two or more kinds thereof.

The shape of the silica powder may be a spherical shape or a non-spherical shape such as an amorphous shape or a crushed shape, and is preferably a spherical shape from the viewpoint of a filling density. The silica powder may be subjected to any surface treatment. Examples of the surface treatment include a treatment for adding a methacrylic group, a vinyl group, a phenyl group, a trimethylsilyl group, a phenylamino group, an epoxy group, or the like to the surface of the silica powder.

The silica powder preferably has a purity of 99.0% or more, more preferably a purity of 99.5% or more, and still more preferably a purity of 99.8% or more.

When a volume-based 50% particle diameter in a cumulative particle size distribution is D₅₀, the D50 of the silica powder is preferably 80 nm or more and 15 μm or less. When the D₅₀ of the silica powder is 80 nm or more, a silica solid content in the green sheet is easily adjusted to 30 vol % or more. Further, when the solid content is high, densification by sintering readily proceeds, and thus a sintered body having an Rq of 300 nm or less is easily obtained. When the D50 of the silica powder is 15 μm or less, it is possible to prevent an increase in sintering temperature, and it is possible to prepare a sintered body such as a quartz glass by sintering. Further, when the D50 of the silica powder is 15 μm or less, the surface unevenness of the sintered body can be prevented, and the surface roughness can be controlled toward a smaller value, so that a sintered body having an Rq of 300 nm or less is easily obtained. The D₅₀ of the silica powder is more preferably 120 nm or more, still more preferably 150 nm or more, even more preferably 300 nm or more, particularly preferably 500 nm or more, and is more preferably 10 μm or less, still more preferably 5 μm or less, even more preferably 2 μm or less, particularly preferably 1 μm or less.

The silica powder preferably contains spherical particles having a ratio (D₁₀/D₅₀) of D₁₀ to D₅₀ of 0.2 or more and 1.0 or less. When the silica powder contains spherical particles having the D₁₀/D₅₀ within the above range, a green sheet is easily prepared. Further, since insufficient densification during sintering can be prevented, a sintered body having an Rq of 300 nm or less is easily obtained. The D₁₀/D₅₀ is more preferably 0.3 or more, still more preferably 0.4 or more, particularly preferably 0.5 or more, and is more preferably 0.9 or less, still more preferably 0.8 or less. By reducing the D₁₀/D₅₀, the particle size distribution can be broadened and the distance between particles can be increased, so that the Rq can be controlled toward a larger value.

The silica powder preferably contains spherical particles having a ratio (D₉₀/D₅₀) of D₉₀ to D₅₀ of 1.0 or more and 3.0 or less. When the silica powder contains spherical particles having the D₉₀/D₅₀ within the above range, a green sheet is easily prepared. Further, since insufficient densification during sintering can be prevented, a sintered body having an Rq of 300 nm or less is easily obtained. The D₉₀/D₅₀ is more preferably 1.2 or more, still more preferably 1.5 or more, particularly preferably 1.7 or more, and is more preferably 2.5 or less, particularly preferably 2.0 or less. By increasing the D₉₀/D₅₀, the particle size distribution can be broadened and the distance between particles can be increased, so that the Rq can be controlled toward a larger value.

Regarding the particle size distribution of the silica powder, by setting the D50 to 80 nm or more and 15 μm or less, the D₁₀/D50 to 0.2 or more and 1.0 or less, and the D₉₀/D50 to 1.0 or more and 3.0 or less, a sintered body having an Rq of 1 nm or more and 300 nm or less is suitably obtained.

Here, the D₅₀, the D₁₀, and the D₉₀ of the silica powder means particle diameters at integrated values of 50%, 10%, and 90% in a particle size distribution obtained by a laser diffraction/scattering method, and can be measured by using, for example, a laser diffraction/scattering particle size analyzer MT-3000 manufactured by Nikkiso Co., Ltd.

### (Binder)

The kind of the binder is not particularly limited, and examples thereof include polyvinyl alcohol-based resins such as polyvinyl alcohol, butyral-based resins such as polyvinyl butyral, cellulose-based resins such as methyl cellulose, ethyl cellulose, hydroxymethyl cellulose, hydroxyethyl cellulose, hydroxypropyl cellulose, hydroxypropyl methyl cellulose, and cellulose acetate phthalate, acrylic resins such as a poly(meth)acrylate ester, nitrile-based resins such as polyacrylonitrile and polymethacrylonitrile, urethane-based resins such as polyurethane, polyethylene, polypropylene, vinyl-based resins such as polyvinylidene fluoride, polyvinylidene chloride, polyvinyl fluoride, and vinyl acetate, rubber-based resins such as a styrene-butadiene rubber, and epoxy-based resins. The binder may be used alone or in combination of two or more kinds thereof. As the binder, a commercially available product may be used.

### (Organic Solvent)

The organic solvent is selected in consideration of compatibility with the binder and a dispersant or a plasticizer to be described later, desired properties of the green sheet, a durable process load, and the like. Examples of the organic solvent include: hydrocarbons such as toluene, xylene, ethylbenzene, methylcyclohexane, and terpineol; alcohols such as ethanol, n-propanol, isopropanol, and n-butanol; ketones such as acetone, methyl ethyl ketone, and methyl isobutyl ketone; ethers such as ethylene glycol monoethyl ether, ethylene glycol monobutyl ether, and propylene glycol monomethyl ether; and esters such as ethyl acetate, butyl acetate, isobutyl acetate, and propylene glycol monomethyl ether acetate. The organic solvent may be used alone or in combination of two or more kinds thereof.

### (Other Components)

The slurry composition may be prepared to contain a dispersant, a plasticizer, an antifoaming agent, a rheology control agent, a wetting agent, and the like as other components.

Examples of the dispersant include a surfactant-type dispersant and a polymer dispersant. The dispersant may be used alone or in combination of two or more kinds thereof.

Examples of the surfactant-type dispersant include alkylamine salts, aliphatic or aromatic quaternary ammonium salts, heterocyclic quaternary ammonium salts such as pyridinium and imidazolium, phosphonium or sulfonium salts containing an aliphatic group or a heterocycle, and acetylene glycol.

Examples of the polymer dispersant include polymers having a primary to tertiary amine, a quaternary ammonium salt group, a quaternary phosphonium salt group, a carboxylic acid group, a hydrochloric acid group, a phosphoric acid group, or the like in a polymer main chain or a side chain, homopolymers of acrylic acid or a salt thereof, or aminocarboxylic acid-based, polyamine-based, polyurethane-based, and polyacrylate-based homopolymers, copolymers, and block copolymers.

As the dispersant, a commercially available product may be used.

Examples of the plasticizer include adipic acid-based, adipic acid ether ester-based, phthalic acid-based, terephthalic acid ester-based, triethylene glycol diester-based, polyether ester-based, and epoxy-based plasticizers. More specifically, bis(2-ethylhexyl) adipate, diisononyl adipate, diisodecyl adipate, di-2-ethylhexyl phthalate, diisononyl phthalate, diisodecyl phthalate, diundecyl phthalate, dibutyl phthalate, dioctyl phthalate, butylbenzyl phthalate, dioctyl terephthalate, triethylene glycol bis(2-ethylhexanoate), (2-ethylhexanoyloxy)triethylene glycol benzoate, triethylene glycol dibenzoate, di-2-ethylhexyl epoxyhexahydrophthalate, di-2-ethylhexyl azelate, di-2-ethylhexyl sebacate, diepoxystearyl epoxyhexahydrophthalate, epoxidized soybean oil, and the like can be used. The plasticizer may be used alone or in combination of two or more kinds thereof. As the plasticizer, a commercially available product or a reagent may be used.

### Forming of Green Sheet

Subsequently, the prepared slurry composition is formed into a green sheet. For example, a support is coated with the prepared slurry composition in sheet form to form a green sheet.

### (Support)

Examples of the support include a resin film.

As the resin film, a thermoplastic resin film is usually used, and specific examples thereof include a polyethylene terephthalate film, a polypropylene film, a polyethylene film, a polycarbonate film, a polyethylene naphthalate film, a polyarylate film, and a nylon film. Among these resin films, a polyethylene terephthalate film and a polyethylene naphthalate film are preferred from the viewpoint of heat resistance, chemical resistance, releasability after lamination, and the like.

The thickness of the support is not particularly limited.

### (Coating Method)

As a method for coating the support with the slurry composition in sheet form, a known wet coating method can be used, and examples thereof include a spin coating method, a doctor blade method, a reverse roll coating method, a spray coating method, a dip coating method, a die coating method, a curtain coating method, a screen coating method, an inkjet method, a flow coating method, a gravure coating method, a bar coating method, a flexographic coating method, a slit coating method, a roll coating method, a sponge roll coating method, and a squeegee coating method.

The slurry composition may be applied onto a support in sheet form such that the green sheet obtained after the drying described later has a thickness of, for example, 10 μm or more and 2.4 mm or less. Accordingly, the thickness of the silica glass substrate obtained after sintering can be adjusted to 10 μm or more and 2 mm or less.

### Drying

The support is coated with the slurry composition in sheet form and then dried to obtain a green sheet.

Drying is a step of removing the organic solvent and the like from the slurry composition applied in a sheet shape on the support, thereby drying the slurry composition.

The drying conditions are appropriately set depending on the kind and the amount of the organic solvent used.

In the present invention, for example, the drying conditions can be set to 60 °C for 4 hours.

### (Green Sheet)

As described above, the green sheet is obtained by drying the slurry composition containing a silica powder, a binder, and an organic solvent, and may contain at least the silica powder and the binder. The green sheet may contain an organic solvent depending on the drying conditions and the like. The green sheet may contain other components described in the section of Slurry Composition, such as a dispersant, a plasticizer, an antifoaming agent, a rheology control agent, and a wetting agent.

### Method for Producing Silica Glass Substrate

Subsequently, the prepared green sheet is sintered to obtain a silica glass substrate as a sintered body.

### (Degreasing)

The organic component in the obtained green sheet may be burned to obtain a degreased body. The degreasing is preferably performed at a temperature of 400 °C to 1,000 °C for 0.5 hours to 80 hours using a heating furnace such as an electric furnace.

### (Sintering)

By sintering the obtained degreased body, a silica glass substrate as a sintered body is obtained. The degreased body may be sintered in a vacuum or in an inert gas atmosphere.

In the case where the degreased body is sintered in a vacuum or in an inert atmosphere, the sintering temperature is preferably, for example, 1,300 °C to 1,550 °C. Here, the sintering temperature is preferably 1,300 °C or higher, more preferably 1,350 °C or higher, and still more preferably 1,400 °C or higher, from the viewpoint of obtaining a silica glass substrate having a high density.

The sintering temperature is preferably 1,550 °C or lower, more preferably 1,500 °C or lower, and still more preferably 1,480 °C or lower, from the viewpoint of preventing cracking of the sintered body due to crystal precipitation.

In the case where the degreased body is sintered in a vacuum or in an inert atmosphere, the sintering time is, for example, 0.03 hours to 5 hours, may be 5 hours to 30 hours, and may be 30 hours to 100 hours.

### (Application)

The silica glass substrate according to the present embodiment is suitably used in high-frequency devices since, even when the substrate surface is metallized, the formed metallized layer is less likely to peel off and high-frequency transmission loss is reduced. In particular, it is suitable for a high-frequency device that handles a high-frequency signal, particularly signals exceeding 30 GHz, and more particularly signals of 70 GHz or more, and can reduce the transmission loss of such high-frequency signals to improve properties such as the quality and the intensity of the high-frequency signals. The silica glass substrate according to the present embodiment is suitable for, for example, a high-frequency device (electronic device) such as a semiconductor device for use in a communication device such as a mobile phone, a smartphone, a mobile information terminal, or a Wi-Fi device, a surface acoustic wave (SAW) device, and a radar component such as a radar transceiver, and an antenna component such as a liquid crystal antenna.

### <Method for Producing Glass Substrate>

The method for producing the glass substrate according to the present embodiment is not particularly limited, and the glass substrate is preferably obtained by sintering a green sheet containing an inorganic powder adjusted to a specific composition. According to this production method, a substrate having a thickness of 2 mm or less can be directly obtained without cutting and polishing, and any surface roughness Rq can be realized without post-processing, so that there is an advantage that a glass substrate in which metallization is less likely to peel off can be easily prepared.

Hereinafter, a method for producing a glass substrate according to the present embodiment by a sintering method is exemplarily described, but the glass substrate according to the present embodiment is not limited to one obtained by this production method. For example, the glass substrate may be obtained by a melting method.

### Preparation of Slurry Composition

As an example of the method for producing a glass substrate according to the present embodiment, first, a slurry composition is prepared. The slurry composition can be obtained by mixing an inorganic powder, a binder, and an organic solvent. In addition, as to be described later, a dispersant, a plasticizer, an antifoaming agent, and the like can also be mixed. The mixing method is not particularly limited, and a known method can be used.

### Inorganic Powder

The inorganic powder contains 60 mol % or more and less than 100 mol % of SiO₂, and is preferably the same as the preferred composition of the glass substrate described above.

For example, a composition satisfying SiO₂: 60 mol % to 90 mol %, B₂O₃: 10 mol % to 35 mol %, and the total of P₂O₅, GeO₂, CaO, MgO, BaO, Li₂O, Na₂O, K₂O, SnO₂, ZnO, and TiO₂: 1 mol % to 15 mol % is exemplified.

The form of the inorganic powder is not particularly limited, and examples thereof include frit obtained by pulverizing a molten glass or a glass bead.

The shape of the inorganic powder may be a spherical shape or a non-spherical shape such as an amorphous shape or a crushed shape, and is preferably a spherical shape from the viewpoint of the filling density.

The inorganic powder preferably has a purity of 99.0% or more, more preferably a purity of 99.5% or more, and still more preferably a purity of 99.8% or more, when the purity of the inorganic powder consisting only of a desired composition is 100% (impurity content: 0%).

When a volume-based 50% particle diameter in a cumulative particle size distribution is defined as D₅₀, the D50 of the inorganic powder is preferably 80 nm or more and 15 μm or less. When the D50 of the inorganic powder is 80 nm or more, an inorganic powder solid content in the green sheet is easily adjusted to 30 vol % or more. Further, when the solid content is high, densification by sintering readily proceeds, and thus a sintered body having an Rq of 300 nm or less is easily obtained. When the D50 of the inorganic powder is 15 μm or less, it is possible to prevent an increase in sintering temperature, and it is possible to prepare a glass sintered body by sintering. Further, when the D50 of the inorganic powder is 15 μm or less, the surface unevenness of the sintered body can be prevented, and the surface roughness can be controlled toward a smaller value, so that a sintered body having an Rq of 300 nm or less is easily obtained.

The D50 of the inorganic powder is more preferably 120 nm or more, still more preferably 150 nm or more, even more preferably 300 nm or more, particularly preferably 500 nm or more, and is more preferably 10 μm or less, still more preferably 5 μm or less, even more preferably 2 μm or less, particularly preferably 1 μm or less.

The inorganic powder preferably contains spherical particles having a ratio (D₁₀/D₅₀) of D₁₀ to D₅₀ of 0.2 or more and 1.0 or less. When the inorganic powder contains spherical particles having the D₁₀/D₅₀ within the above range, a green sheet is easily prepared. Further, since insufficient densification during sintering can be prevented, a sintered body having an Rq of 300 nm or less is easily obtained. The D₁₀/D₅₀ is more preferably 0.3 or more, still more preferably 0.4 or more, particularly preferably 0.5 or more, and is more preferably 0.9 or less, still more preferably 0.8 or less. By reducing the D₁₀/D₅₀, the particle size distribution can be broadened and the distance between particles can be increased, so that the Rq can be controlled toward a larger value.

The inorganic powder preferably contains spherical particles having a ratio (D₉₀/D₅₀) of D₉₀ to D₅₀ of 1.0 or more and 3.0 or less. When the inorganic powder contains spherical particles having the D₉₀/D₅₀ within the above range, a green sheet is easily prepared. Further, since insufficient densification during sintering can be prevented, a sintered body having an Rq of 300 nm or less is easily obtained. The D₉₀/D₅₀ is more preferably 1.2 or more, still more preferably 1.5 or more, particularly preferably 1.7 or more, and is more preferably 2.5 or less, particularly preferably 2.0 or less. By increasing the D₉₀/D₅₀, the particle size distribution can be broadened and the distance between particles can be increased, so that the Rq can be controlled toward a larger value.

Regarding the particle size distribution of the inorganic powder, by setting the D50 to 80 nm or more and 15 μm or less, the D₁₀/D50 to 0.2 or more and 1.0 or less, and the D₉₀/D50 to 1.0 or more and 3.0 or less, a sintered body having an Rq of 1 nm or more and 300 nm or less is suitably obtained.

Here, the D₅₀, the D₁₀, and the D₉₀ of the inorganic powder means particle diameters at integrated values of 50%, 10%, and 90% in a particle size distribution obtained by a laser diffraction/scattering method, and can be measured by using, for example, a laser diffraction/scattering particle size analyzer MT-3000 manufactured by Nikkiso Co., Ltd.

### (Binder)

The kind of the binder is not particularly limited, and examples thereof include polyvinyl alcohol-based resins such as polyvinyl alcohol, butyral-based resins such as polyvinyl butyral, cellulose-based resins such as methyl cellulose, ethyl cellulose, hydroxymethyl cellulose, hydroxyethyl cellulose, hydroxypropyl cellulose, hydroxypropyl methyl cellulose, and cellulose acetate phthalate, acrylic resins such as a poly(meth)acrylate ester, nitrile-based resins such as polyacrylonitrile and polymethacrylonitrile, urethane-based resins such as polyurethane, polyethylene, polypropylene, vinyl-based resins such as polyvinylidene fluoride, polyvinylidene chloride, polyvinyl fluoride, and vinyl acetate, rubber-based resins such as a styrene-butadiene rubber, and epoxy-based resins. The binder may be used alone or in combination of two or more kinds thereof. As the binder, a commercially available product may be used.

### (Organic Solvent)

The organic solvent is selected in consideration of compatibility with the binder, and a dispersant or a plasticizer to be described later, desired properties of the green sheet, a durable process load, and the like. Examples of the organic solvent include: hydrocarbons such as toluene, xylene, ethylbenzene, methylcyclohexane, and terpineol; alcohols such as ethanol, n-propanol, isopropanol, and n-butanol; ketones such as acetone, methyl ethyl ketone, and methyl isobutyl ketone; ethers such as ethylene glycol monoethyl ether, ethylene glycol monobutyl ether, and propylene glycol monomethyl ether; and esters such as ethyl acetate, butyl acetate, isobutyl acetate, and propylene glycol monomethyl ether acetate. The organic solvent may be used alone or in combination of two or more kinds thereof.

### (Other Components)

The slurry composition may be prepared to contain a dispersant, a plasticizer, an antifoaming agent, a rheology control agent, a wetting agent, and the like as other components.

Examples of the dispersant include a surfactant-type dispersant and a polymer dispersant. The dispersant may be used alone or in combination of two or more kinds thereof.

Examples of the surfactant-type dispersant include alkylamine salts, aliphatic or aromatic quaternary ammonium salts, heterocyclic quaternary ammonium salts such as pyridinium and imidazolium, phosphonium or sulfonium salts containing an aliphatic group or a heterocycle, and acetylene glycol.

Examples of the polymer dispersant include polymers having a primary to tertiary amine, a quaternary ammonium salt group, a quaternary phosphonium salt group, a carboxylic acid group, a hydrochloric acid group, a phosphoric acid group, or the like in a polymer main chain or a side chain, homopolymers of acrylic acid or a salt thereof, or aminocarboxylic acid-based, polyamine-based, polyurethane-based, and polyacrylate-based homopolymers, copolymers, and block copolymers.

As the dispersant, a commercially available product may be used.

Examples of the plasticizer include adipic acid-based, adipic acid ether ester-based, phthalic acid-based, terephthalic acid ester-based, triethylene glycol diester-based, polyether ester-based, and epoxy-based plasticizers. More specifically, bis(2-ethylhexyl) adipate, diisononyl adipate, diisodecyl adipate, di-2-ethylhexyl phthalate, diisononyl phthalate, diisodecyl phthalate, diundecyl phthalate, dibutyl phthalate, dioctyl phthalate, butylbenzyl phthalate, dioctyl terephthalate, triethylene glycol bis(2-ethylhexanoate), (2-ethylhexanoyloxy)triethylene glycol benzoate, triethylene glycol dibenzoate, di-2-ethylhexyl epoxyhexahydrophthalate, di-2-ethylhexyl azelate, di-2-ethylhexyl sebacate, diepoxystearyl epoxyhexahydrophthalate, epoxidized soybean oil, and the like can be used. The plasticizer may be used alone or in combination of two or more kinds thereof. As the plasticizer, a commercially available product or a reagent may be used.

### Forming of Green Sheet

Subsequently, the prepared slurry composition is formed into a green sheet. For example, a support is coated with the prepared slurry composition in sheet form to form a green sheet.

### (Support)

Examples of the support include a resin film.

As the resin film, a thermoplastic resin film is usually used, and specific examples thereof include a polyethylene terephthalate film, a polypropylene film, a polyethylene film, a polycarbonate film, a polyethylene naphthalate film, a polyarylate film, and a nylon film. Among these resin films, a polyethylene terephthalate film and a polyethylene naphthalate film are preferred from the viewpoint of heat resistance, chemical resistance, releasability after lamination, and the like.

The thickness of the support is not particularly limited.

### (Coating Method)

As a method for coating the support with the slurry composition in sheet form, a known wet coating method can be used, and examples thereof include a spin coating method, a doctor blade method, a reverse roll coating method, a spray coating method, a dip coating method, a die coating method, a curtain coating method, a screen coating method, an inkjet method, a flow coating method, a gravure coating method, a bar coating method, a flexographic coating method, a slit coating method, a roll coating method, a sponge roll coating method, and a squeegee coating method.

The slurry composition may be applied onto a support in sheet form such that the green sheet obtained after the drying described later has a thickness of, for example, 10 μm or more and 2.4 mm or less. Accordingly, the thickness of the glass substrate obtained after sintering can be adjusted to 10 μm or more and 2 mm or less.

### Drying

The support is coated with the slurry composition in sheet form and then dried to obtain a green sheet.

Drying is a step of removing the organic solvent and the like from the slurry composition applied in a sheet shape on the support, thereby drying the slurry composition.

The drying conditions are appropriately set depending on the kind and the amount of the organic solvent used.

In the present invention, for example, the drying conditions can be set to 60 °C for 4 hours.

### (Green Sheet)

As described above, the green sheet is obtained by drying the slurry composition containing an inorganic powder, a binder, and an organic solvent, and may contain at least the inorganic powder and the binder. The green sheet may contain an organic solvent depending on the drying conditions and the like. The green sheet may contain other components described in the section of Slurry Composition, such as a dispersant, a plasticizer, an antifoaming agent, a rheology control agent, and a wetting agent.

### Production of Glass Substrate

Subsequently, the prepared green sheet is sintered to obtain a glass substrate as a sintered body.

### (Degreasing)

The organic component in the obtained green sheet may be burned to obtain a degreased body. The degreasing is preferably performed at a temperature of 400 °C to 600 °C for 0.5 hours to 80 hours using a heating furnace such as an electric furnace.

### (Sintering)

By sintering the obtained degreased body, a glass substrate as a sintered body is obtained. The degreased body may be sintered in a vacuum or in an inert gas atmosphere.

In the case where the degreased body is sintered in a vacuum or in an inert atmosphere, the sintering temperature is preferably, for example, 600 °C to 1,100 °C. Here, the sintering temperature is preferably 600 °C or higher, more preferably 630 °C or higher, and still more preferably 650 °C or higher, from the viewpoint of obtaining a glass substrate having a high density. The sintering temperature is preferably 1,100 °C or lower, more preferably 1,000 °C or lower, and still more preferably 950 °C or lower, from the viewpoint of preventing cracking of the sintered body due to crystal precipitation.

In the case where the degreased body is sintered in a vacuum or in an inert atmosphere, the sintering time is, for example, 0.03 hours to 5 hours, may be 5 hours to 30 hours, and may be 30 hours to 100 hours.

### (Application)

The glass substrate according to the present embodiment is suitably used in high-frequency devices since, even when the substrate surface is metallized, the formed metallized layer is less likely to peel off and high-frequency transmission loss is reduced. In particular, it is suitable for a high-frequency device that handle a high-frequency signal, particularly signals exceeding 30 GHz, and more particularly signals of 70 GHz or more, and can reduce the transmission loss of such high-frequency signals to improve properties such as the quality and the intensity of the high-frequency signals. The glass substrate according to the present embodiment is suitable for, for example, a high-frequency device (electronic device) such as a semiconductor device for use in a communication device such as a mobile phone, a smartphone, a mobile information terminal, or a Wi-Fi device, a surface acoustic wave (SAW) device, and a radar component such as a radar transceiver, and an antenna component such as a liquid crystal antenna.

### <Metallized Substrate>

The metallized substrate according to one embodiment of the present invention (hereinafter, also simply referred to as a metallized substrate according to the present embodiment) includes a metallized layer provided on the surface of the silica glass substrate or the glass substrate according to the present embodiment described above. FIG. 2 shows a schematic cross-sectional view of a metallized substrate 100 according to the present embodiment, and a metallized layer 20 is provided on the surface of the silica glass substrate 10 according to the present embodiment. The same applies to the case where the metallized layer is provided on the surface of the glass substrate according to the present embodiment.

In the metallized substrate according to the present embodiment, since the metallized layer is provided on the surface of the silica glass substrate or the glass substrate according to the present embodiment described above, the metallized layer is less likely to peel off, and high-frequency transmission loss is reduced.

The metal species contained in the metallized layer is not particularly limited, and may be an alloy or a metal compound containing at least one of the metals described above. Examples thereof include copper, silver, aluminum, titanium, gold, platinum, nickel, tungsten, lead, manganese, magnesium, and chromium.

Examples of a method of providing the metallized layer on the surface of the silica glass substrate or the glass substrate according to the present embodiment include electroplating, electroless plating, chemical vapor deposition (CVD), physical vapor deposition (PVD) such as sputtering, thermal deposition, and electron beam deposition, a printing method, and a dipping method. Hereinafter, a method of providing the metallized layer by electroplating is described, but the present invention is not limited thereto.

In order to provide the metallized layer on the surface of the silica glass substrate or the glass substrate according to the present embodiment by electroplating, first, the silica glass substrate or the glass substrate is put into a plating solution containing an ionic compound having an anion and a cation of a metal for forming the metallized layer, and a current is applied. Accordingly, the elemental metal adheres to the surface of the silica glass substrate or the glass substrate to form a metallized layer containing the metal.

Examples of the anion in the ionic compound containing the cation of the metal to be precipitated include a sulfate anion, a nitrate anion, and a chloride anion. An example of the ionic compound is copper sulfate.

An example of the plating solution is a solution obtained by dissolving copper sulfate pentahydrate (CuSO₄·5H₂O), potassium pyrophosphate (K₄P₂O₇), and citric acid in distilled water. Another example of the plating solution is a solution containing copper sulfate pentahydrate (CuSO₄·5H₂O), manganese sulfate monohydrate (MnSO₄·H₂O), sodium potassium tartrate tetrahydrate (Rochelle salt), and formaldehyde. In some embodiments, the concentration of the ionic compound in the plating solution is 0.001 M (mol/L) or more. In addition to the silica glass substrate or the glass substrate, an electrode made of any conductive material is also put into the plating solution. In some embodiments, the temperature of the plating solution is 10 °C to 50 °C, for example, room temperature or 40 °C.

Then, a current, a voltage, or a combination thereof is applied between the silica glass substrate or the glass substrate and the electrode to supply a negative constant current to the silica glass substrate or the glass substrate. For example, the current is supplied in a current density range of about 0.001 mA/cm² to about 1 A/cm² and a voltage range of about-0.001 V to about-20 V. Accordingly, the cation of the metal to be the metallized layer is reduced to an elemental form on the silica glass substrate or the glass substrate. The rate of the reduction reaction is controlled by the current density. Therefore, the deposition rate can be increased or decreased by increasing or decreasing the applied current.

Then, once the metallized layer containing the desired metal is provided on the silica glass substrate or the glass substrate, the current may be stopped, the silica glass substrate or the glass substrate may be taken out from the plating solution, and the silica glass substrate or the glass substrate provided with the metallized layer may be washed with deionized water. The silica glass substrate or the glass substrate provided with the metallized layer may be optionally dried by, for example, flowing a nitrogen stream on the silica glass substrate or the glass substrate provided with the metallized layer.

In the metallized substrate according to the present embodiment, the thickness of the metallized layer is preferably 0.01 μm to 100 μm, more preferably 0.1 μm to 50 μm, and still more preferably 1 μm to 25 μm. When the thickness of the metallized layer is within the above range, it is possible to minimize loss or reflection generated when a high-frequency signal passes through the metallized layer.

As described above, the following matters are disclosed in the present description.
[1] A silica glass substrate having a root mean square height Rq of 1 nm or more and 300 nm or less on a substrate surface, and a thickness of 10 μm or more and 2 mm or less.
[2] The silica glass substrate according to [1], in which the number of defects having an average diameter of 1 μm or more and 100 μm or less is 500,000 or less per cm².
[3] The silica glass substrate according to [1] or [2], in which an H₂O concentration converted from β-OH is less than 100 ppm by mass.
[4] The silica glass substrate according to any one of [1] to [3], in which a total content of Na, K, and Ca is 0.1 ppm by mass or more and 50 ppm by mass or less.
[5] The silica glass substrate according to any one of [1] to [4], in which a content of C is 5 ppm by mass or less.
[6] The silica glass substrate according to any one of [1] to [5], in which a content of Zr is 50 ppm by mass or less.
[7] The silica glass substrate according to any one of [1] to [6], in which a content of Ti is 50 ppm by mass or less.
[8] The silica glass substrate according to any one of [1] to [7], in which a content of Al is 50 ppm by mass or less.
[9] The silica glass substrate according to any one of [1] to [8], in which a ratio (D2/PH) of an intensity (D2) to a height (PH) of a peak derived from a three-membered ring structure in a Raman spectrum is 0.10 or more.
[10] The silica glass substrate according to any one of [1] to [9], in which a ratio (D1/PH) of an intensity (D1) to a height (PH) of a peak derived from a four-membered ring structure in a Raman spectrum is 0.40 or more.
[11] The silica glass substrate according to any one of [1] to [10], which is used in a high-frequency device.
[12] A metallized substrate including the silica glass substrate according to any one of [1] to [10] and a metallized layer provided on a surface of the silica glass substrate.
[13] A glass substrate having a root mean square height Rq of 1 nm or more and 300 nm or less on a substrate surface, and a thickness of 10 μm or more and 2 mm or less, in which the glass substrate includes 60 mol % or more and less than 100 mol % of SiO₂ as represented by mol % based on oxides.
[14] The glass substrate according to [13], further including 10 mol % or more and 35 mol % or less of B₂O₃ as represented by mol % based on oxides.
[15] The glass substrate according to [13] or [14], further including at least one of P₂O₅, GeO₂, CaO, MgO, BaO, Li₂O, Na₂O, K₂O, SnO₂, ZnO, and TiO₂ as represented by mol % based on oxides, in which a total content thereof is 1 mol % or more and 15 mol % or less.
[16] The glass substrate according to any one of [13] to [15], in which a total content of Na, K, and Ca is 0.1 ppm by mass or more and 50 ppm by mass or less.
[17] The glass substrate according to any one of [13] to [15], in which a content of Cis 5 ppm by mass or less.
[18] The glass substrate according to any one of [13] to [17], in which a content of Zr is 50 ppm by mass or less.
[19] The glass substrate according to any one of [13] to [18], in which a content of Ti is 50 ppm by mass or less.
[20] The glass substrate according to any one of [13] to [19], in which a content of Al is 50 ppm by mass or less.
[21] The glass substrate according to any one of [13] to [20], which is used in a high-frequency device.
[22] A metallized substrate including the glass substrate according to any one of [13] to [20] and a metallized layer provided on a surface of the glass substrate.

### EXAMPLES

Hereinafter, the present invention is specifically described with reference to Examples, but the present invention is not limited thereto. Examples 1 to 13 are Inventive Examples, and Example 14 is a Comparative Example. Examples 1 to 6 and 14 are silica glass substrates, and Examples 7 to 13 are glass substrates.

The blank in Table 1 means that measurement was not performed.

### (Amount of C)

The amount of impurities (amount of C) in the silica glass substrate and the glass substrate in each example was measured by a carbon analyzer (EMIA-Pro, manufactured by Horiba, Ltd.). The measurement results in each example are shown in Table 1.

### (Amounts of Al, Zr, and Ti)

The amounts of impurities (amounts of Al, Zr, and Ti) in the silica glass substrate and the glass substrate in each example were measured by an ICP mass spectrometer (Agilent 8800, manufactured by Agilent Technologies, Inc.). The measurement results in each example are shown in Table 1.

### (Total Content of Na, K, and Ca)

The total content of Na, K, and Ca in the silica glass substrate and the glass substrate in each example was measured by an ICP mass spectrometer (Agilent 8800, manufactured by Agilent Technologies, Inc.). The measurement results in each example are shown in Table 1.

### (H₂O)

The β-OH in the silica glass substrate in each example was measured by a Fourier transform infrared spectrophotometer (IRXross, manufactured by Shimadzu Corporation), and the H₂O concentration was calculated. The result in each example is shown in Table 1.

### (Defects)

The number of defects having an average diameter of 5 μm or more and 100 μm or less per cm², the number of defects having an average diameter of 1 μm or more and 5 μm or less per cm², and the number of defects having an average diameter of 1 μm or more and 100 μm or less per cm² in the silica glass substrate and the glass substrate in each example were measured by processing a microscope image obtained using an optical microscope (VHX8000, manufactured by Keyence Corporation) with image analysis software (Imagepro, manufactured by Hakuto Co., Ltd.). The average diameter means the average of diameters each connecting two points on the outer periphery of a defect extracted based on the color and shape of the pattern and passing through the center of gravity, in an optical microscope image in which a glass portion is selected as the background using image analysis software. The measurement results in each example are shown in Table 1.

### (Raman Spectrum)

Raman spectroscopic analysis was performed using a microscopic laser Raman spectrometer (LabRAM HR Evolution, manufactured by Horiba, Ltd.) to obtain a scattered light intensity (y) over a Raman shift (x) range of 100 cm⁻¹ to 720 cm⁻¹, namely, the Raman spectrum. The measurement region was a cylindrical region located 5 μm below the surface of the silica glass substrate in each example and having a diameter of about 3 μm and a length of about 3 um.

Based on the obtained Raman spectrum, the ratio (D2/PH) of the peak (D2) derived from the three-membered ring structure to the height (PH) and the ratio (D1/PH) of the peak (D1) derived from the four-membered ring structure to the height (PH) were determined. The measurement results in each example are shown in Table 1. FIG. 3 shows the Raman spectrum of Example 5.

### (Rq)

The root mean square height Rq on the surface of the silica glass substrate and the glass substrate in each example was measured using a surface roughness measuring device (SURFCOM 1400D, manufactured by Tokyo Seimitsu Co., Ltd.) based on JIS B 0601 (2013). The measurement results in each example are shown in Table 1.

### (Df)

The Df (dielectric loss tangent) of the silica glass substrate and the glass substrate in each example at 10 GHz was measured by a dielectric resonator method.

### (Etching Rate (Relative Value))

The etching rate for the silica glass substrate and the glass substrate in each example was calculated by immersing a silica glass substrate masked with Kapton tape in an aqueous solution containing 8 wt % HF and 7 wt % HNO₃ for 5 hours, removing the mask, and calculating the etching rate from step height measurement results obtained using a stylus-type surface profilometer (Dektak 150, manufactured by Bruker). Then, the relative value when the etching rate of a synthetic quartz glass (AQ, manufactured by AGC Inc.) was 1 was determined. The results are shown in Table 1.

### (Plating Adhesion Test)

The surfaces of the silica glass substrate and the glass substrate were plated with Cu to a thickness of 0.07 μm by a sputtering method, and the test was performed in accordance with the tape test method in the plating adhesion test method defined in JIS H 8504:1999. The test area was visually observed, and when peeling or swelling of the plating was clearly observed, it was evaluated as B, and otherwise, it was evaluated as A.

### <Preparation of Silica Glass Substrate and Glass Substrate>

### Example 1

A spherical silica powder having a volume-based 50% particle diameter D50 of 2,180 nm in the cumulative particle size distribution, a volume-based 10% particle diameter D₁₀ of 1,046 nm in the cumulative particle size distribution, a volume-based 90% particle diameter D₉₀ of 3,750 nm in the cumulative particle size distribution, a ratio (D₁₀/D₅₀) of D₁₀ to D₅₀ of 0.48, and a ratio (D₉₀/D₅₀) of D₉₀ to D₅₀ of 1.72 was prepared, and organic solvents were weighed so as to have a proportion of 45 mass % of propylene glycol monomethyl ether acetate, 30 mass % of 2-butanol, and 25 mass % of isopropyl alcohol, to which a dispersant (a polymer dispersant having an ammonium salt group in a polymer side chain) was added in an amount of 4 mass % with respect to the silica powder and a plasticizer (a commercially available product of an adipic acid ether ester-based plasticizer) was added in an amount of 5 mass % with respect to the silica powder, followed by mixing in a ball mill. A solution of polyvinyl butyral at a component proportion of 22.4 mass % was prepared as a binder, weighed so as to be 5 mass % with respect to the silica powder, and added to the ball mill container. At this time, a solvent in the binder was the same as a solvent composition in a dispersion slurry.

The obtained slurry was subjected to a defoaming treatment under a reduced pressure condition and applied onto a PET (polyethylene terephthalate) film by a doctor blade method to form a green sheet having a thickness of 0.18 mm.

The obtained green sheet was dried at 60 °C for 4 hours and cut using a disc cutter to obtain sheet formed body. This sheet formed body was degreased at 600 °C for 1 hour and then sintered at 1,460 °C for 5 minutes in a vacuum to obtain a silica glass substrate as a sintered body having a thickness of 0.15 mm.

### Example 2

A spherical silica powder having a volume-based 50% particle diameter D50 of 2,180 nm in the cumulative particle size distribution, a volume-based 10% particle diameter D₁₀ of 1,046 nm in the cumulative particle size distribution, a volume-based 90% particle diameter D₉₀ of 3,750 nm in the cumulative particle size distribution, a ratio (D₁₀/D₅₀) of Dio to D₅₀ of 0.48, and a ratio (D₉₀/D₅₀) of D₉₀ to D₅₀ of 1.72 was prepared, and an organic solvent was weighed so as to have a proportion of 100 mass % of propylene glycol monomethyl ether acetate, to which a dispersant (a polymer dispersant having an ammonium salt group in a polymer side chain) was added in an amount of 4 mass % with respect to the silica powder and a plasticizer (a commercially available product of an adipic acid ether ester-based plasticizer) was added in an amount of 5 mass % with respect to the silica powder, followed by mixing in a ball mill. A solution of polyvinyl butyral at a component proportion of 22.4 mass % was prepared as a binder, weighed so as to be 5 mass % with respect to the silica powder, and added to the ball mill container. At this time, a solvent in the binder was the same as a solvent composition in a dispersion slurry.

The obtained slurry was subjected to a defoaming treatment under a reduced pressure condition and applied onto a PET film by a doctor blade method to form a green sheet having a thickness of 0.10 mm.

The obtained green sheet was dried at 60 °C for 4 hours and cut using a disc cutter to obtain sheet formed body. This sheet formed body was degreased at 600 °C for 1 hour and then sintered at 1,460 °C for 5 minutes in a vacuum to obtain a silica glass substrate as a sintered body having a thickness of 0.08 mm.

### Example 3

A spherical silica powder having a volume-based 50% particle diameter D50 of 500 nm in the cumulative particle size distribution, a volume-based 10% particle diameter D₁₀ of 330 nm in the cumulative particle size distribution, a volume-based 90% particle diameter D₉₀ of 640 nm in the cumulative particle size distribution, a ratio (D₁₀/D₅₀) of Dio to D₅₀ of 0.66, and a ratio (D₉₀/D₅₀) of D₉₀ to D₅₀ of 1.28 was prepared, and organic solvents were weighed so as to have a proportion of 45 mass % of propylene glycol monomethyl ether acetate, 30 mass % of 2-butanol, and 25 mass % of isopropyl alcohol, to which a dispersant (a polymer dispersant having an ammonium salt group in a polymer side chain) was added in an amount of 4 mass % with respect to the silica powder and a plasticizer (a commercially available product of an adipic acid ether ester-based plasticizer) was added in an amount of 7 mass % with respect to the silica powder, followed by mixing in a ball mill. A solution of polyvinyl butyral at a component proportion of 22.4 mass % was prepared as a binder, weighed so as to be 14 mass % with respect to the silica powder, and added to the ball mill container. At this time, a solvent in the binder was the same as a solvent composition in a dispersion slurry.

The obtained slurry was subjected to a defoaming treatment under a reduced pressure condition and applied onto a PET film by a doctor blade method to form a green sheet having a thickness of 0.27 mm.

The obtained green sheet was dried at 60 °C for 4 hours and cut using a disc cutter to obtain sheet formed body. This sheet formed body was degreased at 550 °C for 1 hour and then sintered at 1,550 °C for 5 minutes in a vacuum to obtain a silica glass substrate as a sintered body having a thickness of 0.225 mm.

### Example 4

A spherical silica powder having a volume-based 50% particle diameter D50 of 500 nm in the cumulative particle size distribution, a volume-based 10% particle diameter D₁₀ of 330 nm in the cumulative particle size distribution, a volume-based 90% particle diameter D₉₀ of 640 nm in the cumulative particle size distribution, a ratio (D₁₀/D₅₀) of Dio to D₅₀ of 0.66, and a ratio (D₉₀/D₅₀) of D₉₀ to D₅₀ of 1.28 was prepared, and organic solvents were weighed so as to have a proportion of 45 mass % of propylene glycol monomethyl ether acetate, 30 mass % of 2-butanol, and 25 mass % of isopropyl alcohol, to which a dispersant (a polymer dispersant having an ammonium salt group in a polymer side chain) was added in an amount of 4 mass % with respect to the silica powder and a plasticizer (a commercially available product of an adipic acid ether ester-based plasticizer) was added in an amount of 5 mass % with respect to the silica powder, followed by mixing in a ball mill. A solution of polyvinyl butyral at a component proportion of 22.4 mass % was prepared as a binder, weighed so as to be 10 mass % with respect to the silica powder, and added to the ball mill container. At this time, a solvent in the binder was the same as a solvent composition in a dispersion slurry.

The obtained slurry was subjected to a defoaming treatment under a reduced pressure condition and applied onto a PET film by a doctor blade method to form a green sheet having a thickness of 0.20 mm.

The obtained green sheet was dried at 60 °C for 4 hours and cut using a disc cutter to obtain sheet formed body. This sheet formed body was degreased at 550 °C for 1 hour and then sintered at 1,510 °C for 5 minutes in a vacuum to obtain a silica glass substrate as a sintered body having a thickness of 0.168 mm.

### Example 5

A spherical silica powder having a volume-based 50% particle diameter D50 of 590 nm in the cumulative particle size distribution, a volume-based 10% particle diameter D₁₀ of 242 nm in the cumulative particle size distribution, a volume-based 90% particle diameter D₉₀ of 838 nm in the cumulative particle size distribution, a ratio (D₁₀/D₅₀) of D₁₀ to D₅₀ of 0.41, and a ratio (D₉₀/D₅₀) of D₉₀ to D₅₀ of 1.42 was prepared, and organic solvents were weighed so as to have a proportion of 45 mass % of propylene glycol monomethyl ether acetate, 15 mass % of 2-butanol, 15 mass % of xylene, and 25 mass % of isopropyl alcohol, to which a dispersant (a polymer dispersant having an ammonium salt group in a polymer side chain) was added in an amount of 1 mass % with respect to the silica powder and a plasticizer (a commercially available product of an adipic acid ether ester-based plasticizer) was added in an amount of 3 mass % with respect to the silica powder, followed by mixing in a ball mill. A solution of an acrylic resin at a component proportion of 30 mass % was prepared as a binder, weighed so as to be 10 mass % with respect to the silica powder, and added to the ball mill container. At this time, a solvent in the binder was the same as a solvent composition in a dispersion slurry.

The obtained slurry was subjected to a defoaming treatment under a reduced pressure condition and applied onto a PET film by a doctor blade method to form a green sheet having a thickness of 0.28 mm.

The obtained green sheet was dried at 90 °C for 1 hour and cut using a disc cutter to obtain sheet formed body. This sheet formed body was degreased at 550 °C for 1 hour and then sintered at 1,470 °C for 5 minutes in a vacuum to obtain a silica glass substrate as a sintered body having a thickness of 0.245 mm.

### Example 6

A spherical silica powder having a volume-based 50% particle diameter D50 of 500 nm in the cumulative particle size distribution, a volume-based 10% particle diameter D₁₀ of 330 nm in the cumulative particle size distribution, a volume-based 90% particle diameter D₉₀ of 640 nm in the cumulative particle size distribution, a ratio (D₁₀/D₅₀) of D₁₀ to D₅₀ of 0.66, and a ratio (D₉₀/D₅₀) of D₉₀ to D₅₀ of 1.28 was prepared, and organic solvents were weighed so as to have a proportion of 45 mass % of propylene glycol monomethyl ether acetate, 30 mass % of 2-butanol, and 25 mass % of isopropyl alcohol, to which a dispersant (a polymer dispersant having an ammonium salt group in a polymer side chain) was added in an amount of 4 mass % with respect to the silica powder and a plasticizer (a commercially available product of an adipic acid ether ester-based plasticizer) was added in an amount of 7 mass % with respect to the silica powder, followed by mixing in a ball mill. A solution of a polyvinyl butyral resin at a component proportion of 22.4 mass % was prepared as a binder, weighed so as to be 14 mass % with respect to the silica powder, and added to the ball mill container. At this time, a solvent in the binder was the same as a solvent composition in a dispersion slurry.

The obtained slurry was subjected to a defoaming treatment under a reduced pressure condition and applied onto a PET film by a doctor blade method to form a green sheet having a thickness of 0.24 mm.

The obtained green sheet was dried at 90 °C for 1 hour and cut using a disc cutter to obtain sheet formed body. This sheet formed body was degreased at 550 °C for 1 hour and then sintered at 1,550 °C for 5 minutes in a vacuum to obtain a silica glass substrate as a sintered body having a thickness of 0.203 mm.

### Example 7

A spherical inorganic powder having a volume-based 50% particle diameter D₅₀ of 3,252 nm in the cumulative particle size distribution, a volume-based 10% particle diameter D₁₀ of 2,106 nm in the cumulative particle size distribution, a volume-based 90% particle diameter D₉₀ of 5,182 nm in the cumulative particle size distribution, a ratio (D₁₀/D₅₀) of Dio to D₅₀ of 0.41, and a ratio (D₉₀/D₅₀) of D₉₀ to D₅₀ of 2.46 was prepared. The inorganic powder is amorphous particles composed of 75 mol % of SiO₂ and 25 mol % of B₂O₃.

Solvents were weighed so as to have the following proportions and added to the inorganic powder: 45 mass % of propylene glycol monomethyl ether acetate, 30 mass % of 2-butanol, and 25 mass % of isopropyl alcohol, to which a dispersant (a polymer dispersant having an ammonium salt group in a polymer side chain) was added in an amount of 1 mass % with respect to the inorganic powder and a plasticizer (a commercially available product of an adipic acid ether ester-based plasticizer) was added in an amount of 3 mass % with respect to the inorganic powder, followed by mixing in a ball mill. A solution of a polyvinyl butyral resin at a component proportion of 22.4 mass % was prepared as a binder, weighed so as to be 10 mass % with respect to the inorganic powder, and added to the ball mill container. At this time, a solvent in the binder was the same as a solvent composition in a dispersion slurry.

The obtained slurry was subjected to a defoaming treatment under a reduced pressure condition and applied onto a PET film by a doctor blade method to form a green sheet having a thickness of 0.24 mm.

The obtained green sheet was dried at 90 °C for 1 hour and cut using a disc cutter to obtain sheet formed body. This sheet formed body was degreased at 550 °C for 1 hour and then sintered at 800 °C for 5 minutes in a vacuum to obtain a glass substrate as a sintered body having a thickness of 0.200 mm.

### Example 8

A spherical inorganic powder having a volume-based 50% particle diameter D₅₀ of 3,470 nm in the cumulative particle size distribution, a volume-based 10% particle diameter D₁₀ of 2,117 nm in the cumulative particle size distribution, a volume-based 90% particle diameter D₉₀ of 5,936 nm in the cumulative particle size distribution, a ratio (D₁₀/D₅₀) of D₁₀ to D₅₀ of 0.36, and a ratio (D₉₀/D₅₀) of D₉₀ to D₅₀ of 2.80 was prepared. The inorganic powder is amorphous particles composed of 80 mol % of SiO₂ and 20 mol % of B₂O₃.

Solvents were weighed so as to have the following proportions and added to the inorganic powder: 45 mass % of propylene glycol monomethyl ether acetate, 30 mass % of 2-butanol, and 25 mass % of isopropyl alcohol, to which a dispersant (a polymer dispersant having an ammonium salt group in a polymer side chain) was added in an amount of 1 mass % with respect to the inorganic powder and a plasticizer (a commercially available product of an adipic acid ether ester-based plasticizer) was added in an amount of 3 mass % with respect to the inorganic powder, followed by mixing in a ball mill. A solution of a polyvinyl butyral resin at a component proportion of 22.4 mass % was prepared as a binder weighed so as to be 10 mass % with respect to the inorganic powder, and added to the ball mill container. At this time, a solvent in the binder was the same as a solvent composition in a dispersion slurry.

The obtained slurry was subjected to a defoaming treatment under a reduced pressure condition and applied onto a PET film by a doctor blade method to form a green sheet having a thickness of 0.10 mm.

The obtained green sheet was dried at 90 °C for 0.5 hours and cut using a disc cutter to obtain sheet formed body. This sheet formed body was degreased at 550 °C for 1 hour and then sintered at 810 °C for 5 minutes in a vacuum to obtain a glass substrate as a sintered body having a thickness of 0.090 mm.

### Example 9

A spherical inorganic powder having a volume-based 50% particle diameter D₅₀ of 3,470 nm in the cumulative particle size distribution, a volume-based 10% particle diameter D₁₀ of 2,117 nm in the cumulative particle size distribution, a volume-based 90% particle diameter D₉₀ of 5,936 nm in the cumulative particle size distribution, a ratio (D₁₀/D₅₀) of Dio to D₅₀ of 0.36, and a ratio (D₉₀/D₅₀) of D₉₀ to D₅₀ of 2.80 was prepared. The inorganic powder is amorphous particles composed of 85 mol % of SiO₂ and 15 mol % of B₂O₃.

Organic solvents were weighed so as to have the following proportions and added to the inorganic powder: 45 mass % of propylene glycol monomethyl ether acetate, 30 mass % of 2-butanol, and 25 mass % of isopropyl alcohol, to which a dispersant (a polymer dispersant having an ammonium salt group in a polymer side chain) was added in an amount of 1 mass % with respect to the inorganic powder and a plasticizer (a commercially available product of an adipic acid ether ester-based plasticizer) was added in an amount of 3 mass % with respect to the inorganic powder, followed by mixing in a ball mill. A solution of a polyvinyl butyral resin at a component proportion of 22.4 mass % was prepared as a binder weighed so as to be 10 mass % with respect to the inorganic powder, and added to the ball mill container. At this time, a solvent in the binder was the same as a solvent composition in a dispersion slurry.

The obtained slurry was subjected to a defoaming treatment under a reduced pressure condition and applied onto a PET film by a doctor blade method to form a green sheet having a thickness of 0.18 mm.

The obtained green sheet was dried at 90 °C for 0.5 hours and cut using a disc cutter to obtain sheet formed body. This sheet formed body was degreased at 550 °C for 1 hour and then sintered at 830 °C for 5 minutes in a vacuum to obtain a glass substrate as a sintered body having a thickness of 0.150 mm.

### Example 10

A spherical inorganic powder having a volume-based 50% particle diameter D₅₀ of 3,470 nm in the cumulative particle size distribution, a volume-based 10% particle diameter D₁₀ of 2,117 nm in the cumulative particle size distribution, a volume-based 90% particle diameter D₉₀ of 5,936 nm in the cumulative particle size distribution, a ratio (D₁₀/D₅₀) of D₁₀ to D₅₀ of 0.36, and a ratio (D₉₀/D₅₀) of D₉₀ to D₅₀ of 2.80 was prepared. The inorganic powder is amorphous particles composed of 90 mol % of SiO₂ and 10 mol % of B₂O₃.

Organic solvents were weighed so as to have a proportion of 45 mass % of propylene glycol monomethyl ether acetate, 30 mass % of 2-butanol, and 25 mass % of isopropyl alcohol, to which a dispersant (a polymer dispersant having an ammonium salt group in a polymer side chain) was added in an amount of 1 mass % with respect to the inorganic powder and a plasticizer (a commercially available product of an adipic acid ether ester-based plasticizer) was added in an amount of 3 mass % with respect to the inorganic powder, followed by mixing in a ball mill. A solution of a polyvinyl butyral resin at a component proportion of 22.4 mass % was prepared as a binder, weighed so as to be 10 mass % with respect to the inorganic powder, and added to the ball mill container. At this time, a solvent in the binder was the same as a solvent composition in a dispersion slurry.

The obtained slurry was subjected to a defoaming treatment under a reduced pressure condition and applied onto a PET film by a doctor blade method to form a green sheet having a thickness of 0.18 mm.

The obtained green sheet was dried at 90 °C for 0.5 hours and cut using a disc cutter to obtain sheet formed body. This sheet formed body was degreased at 550 °C for 1 hour and then sintered at 850 °C for 5 minutes in a vacuum to obtain a glass substrate as a sintered body having a thickness of 0.150 mm.

### Example 11

An inorganic powder having a volume-based 50% particle diameter D50 of 3,499 nm in the cumulative particle size distribution, a volume-based 10% particle diameter D₁₀ of 2,458 nm in the cumulative particle size distribution, a volume-based 90% particle diameter D₉₀ of 5,308 nm in the cumulative particle size distribution, a ratio (D₁₀/D₅₀) of D₁₀ to D₅₀ of 0.46, and a ratio (D₉₀/D₅₀) of D₉₀ to D₅₀ of 2.16 was prepared. The inorganic powder is amorphous particles composed of 80 mol % of SiO₂, 15 mol % of B₂O₃, and 5 mol % of MgO.

A solvent was weighed so as to have a proportion of 100 mass % of propylene glycol monomethyl ether acetate and added to the inorganic powder, to which a dispersant (a polymer dispersant having an ammonium salt group in a polymer side chain) was added in an amount of 1 mass % with respect to the inorganic powder and a plasticizer (a commercially available product of an adipic acid ether ester-based plasticizer) was added in an amount of 3 mass % with respect to the inorganic powder, followed by mixing in a ball mill. A solution of an acrylic resin at a component proportion of 22.4 mass % was prepared as a binder, weighed so as to be 10 mass % with respect to the inorganic powder, and added to the ball mill container. At this time, a solvent in the binder was the same as a solvent composition in a dispersion slurry.

The obtained slurry was subjected to a defoaming treatment under a reduced pressure condition and applied onto a PET film by a doctor blade method to form a green sheet having a thickness of 0.23 mm.

The obtained green sheet was dried at 90 °C for 0.5 hours and cut using a disc cutter to obtain sheet formed body. This sheet formed body was degreased at 550 °C for 1 hour and then sintered at 810 °C for 5 minutes in a vacuum to obtain a glass substrate as a sintered body having a thickness of 0.20 mm.

### Example 12

An inorganic powder having a volume-based 50% particle diameter D50 of 3,234 nm in the cumulative particle size distribution, a volume-based 10% particle diameter D₁₀ of 2,198 nm in the cumulative particle size distribution, a volume-based 90% particle diameter D₉₀ of 4,961 nm in the cumulative particle size distribution, a ratio (D₁₀/D₅₀) of Dio to D₅₀ of 0.44, and a ratio (D₉₀/D₅₀) of D₉₀ to D₅₀ of 2.26 was prepared. The inorganic powder is amorphous particles composed of 80 mol % of SiO₂, 15 mol % of B₂O₃, and 5 mol % of SnO.

A solvent was weighed so as to have a proportion of 100 mass % of propylene glycol monomethyl ether acetate and added to the inorganic powder, to which a dispersant (a polymer dispersant having an ammonium salt group in a polymer side chain) was added in an amount of 1 mass % with respect to the inorganic powder and a plasticizer (a commercially available product of an adipic acid ether ester-based plasticizer) was added in an amount of 3 mass % with respect to the inorganic powder, followed by mixing in a ball mill. A solution of an acrylic resin at a component proportion of 22.4 mass % was prepared as a binder, weighed so as to be 10 mass % with respect to the inorganic powder, and added to the ball mill container. At this time, a solvent in the binder was the same as a solvent composition in a dispersion slurry.

The obtained slurry was subjected to a defoaming treatment under a reduced pressure condition and applied onto a PET film by a doctor blade method to form a green sheet having a thickness of 0.23 mm.

The obtained green sheet was dried at 90 °C for 0.5 hours and cut using a disc cutter to obtain sheet formed body. This sheet formed body was degreased at 550 °C for 1 hour and then sintered at 810 °C for 5 minutes in a vacuum to obtain a glass substrate as a sintered body having a thickness of 0.20 mm.

### Example 13

An inorganic powder having a volume-based 50% particle diameter D50 of 4,491 nm in the cumulative particle size distribution, a volume-based 10% particle diameter D₁₀ of 2,172 nm in the cumulative particle size distribution, a volume-based 90% particle diameter D₉₀ of 10,030 nm in the cumulative particle size distribution, a ratio (D₁₀/D₅₀) of Dio to D₅₀ of 0.22, and a ratio (D₉₀/D₅₀) of D₉₀ to D₅₀ of 4.62 was prepared. The inorganic powder is amorphous particles composed of 80 mol % of SiO₂, 15 mol % of B₂O₃, and 5 mol % of ZnO.

A solvent was weighed so as to have a proportion of 100 mass % of propylene glycol monomethyl ether acetate and added to the inorganic powder, to which a dispersant (a polymer dispersant having an ammonium salt group in a polymer side chain) was added in an amount of 1 mass % with respect to the inorganic powder and a plasticizer (a commercially available product of an adipic acid ether ester-based plasticizer) was added in an amount of 3 mass % with respect to the inorganic powder, followed by mixing in a ball mill. A solution of a polyvinyl butyral resin at a component proportion of 22.4 mass % was prepared as a binder, weighed so as to be 10 mass % with respect to the inorganic powder, and added to the ball mill container. At this time, a solvent in the binder was the same as a solvent composition in a dispersion slurry.

The obtained slurry was subjected to a defoaming treatment under a reduced pressure condition and applied onto a PET film by a doctor blade method to form a green sheet having a thickness of 0.23 mm.

The obtained green sheet was dried at 90 °C for 0.5 hours and cut using a disc cutter to obtain sheet formed body. This sheet formed body was degreased at 550 °C for 1 hour and then sintered at 800 °C for 5 minutes in a vacuum to obtain a glass substrate as a sintered body having a thickness of 0.20 mm.

### Example 14

Example 14 was a synthetic quartz glass substrate (AQ, manufactured by AGC Inc.) having an Rq of 0.0001 μm.

TABLE 1

| | Raw material (silica powder | | | | | Silica glass substrate or glass substrate | | | | | |
|---|---|---|---|---|---|---|---|---|---|---|---|
| | or inorganic powder) | | | | | Impurities | | | | Na + K + | |
| | D₅₀ | D₁₀ | D₉₀ | D₁₀/D₅₀ | D₉₀/D₅₀ | C | Al | Zr | Ti | Ca | H₂O |
| | nm | nm | nm | — | — | ppm | ppm | ppm | ppm | ppm | ppm |
| Example | 2180 | 1046 | 3750 | 0.48 | 1.72 | <1 | 38 | 0.5 | 1.2 | 8 | |
| 1 | | | | | | | | | | | |
| Example | 2180 | 1046 | 3750 | 0.48 | 1.72 | <1 | 11 | 0.1 | 0.3 | 5.6 | |
| 2 | | | | | | | | | | | |
| Example | 500 | 330 | 640 | 0.66 | 1.28 | <1 | 1.3 | 0.1 | 0.1 | 4.4 | 1.3 |
| 3 | | | | | | | | | | | |
| Example | 500 | 330 | 640 | 0.66 | 1.28 | <1 | 42 | 0.3 | 2.6 | 4.9 | <1.1 |
| 4 | | | | | | | | | | | |
| Example | 590 | 242 | 838 | 0.41 | 1.42 | <1 | 0.9 | <0.1 | <0.1 | 1.1 | <0.8 |
| 5 | | | | | | | | | | | |
| Example | 500 | 330 | 640 | 0.66 | 1.28 | <1 | 0.6 | <0.1 | 31 | 4.2 | <1.0 |
| 6 | | | | | | | | | | | |
| Example | 3252 | 2106 | 5182 | 0.41 | 2.46 | 3 | 0.6 | <0.1 | <0.1 | <0.1 | |
| 7 | | | | | | | | | | | |
| Example | 3470 | 2117 | 5936 | 0.36 | 2.80 | <1 | 0.1 | <0.1 | <0.1 | 0.1 | |
| 8 | | | | | | | | | | | |
| Example | 3470 | 2117 | 5936 | 0.36 | 2.80 | <1 | 10 | 0.5 | 0.1 | 1.5 | |
| 9 | | | | | | | | | | | |
| Example | 3470 | 2117 | 5936 | 0.36 | 2.80 | <1 | 0.6 | <0.1 | 15 | 5.5 | |
| 10 | | | | | | | | | | | |
| Example | 3499 | 2458 | 5308 | 0.46 | 2.16 | | | | | | |
| 11 | | | | | | | | | | | |
| Example | 3234 | 2198 | 4961 | 0.44 | 2.26 | | | | | | |
| 12 | | | | | | | | | | | |
| Example | 4491 | 2172 | 10030 | 0.22 | 4.62 | | | | | | |
| 13 | | | | | | | | | | | |
| Example | | | | | | <0.1 | <0.1 | <0.1 | <0.1 | <0.1 | 56 |
| 14 | | | | | | | | | | | |

| | Silica glass substrate or glass substrate | | | | | | | | | |
|---|---|---|---|---|---|---|---|---|---|---|
| | Defects (per cm²) | | | | | | | | Etching | |
| | Average | Average | Average | Raman | | | | | rate | |
| | diameter: | diameter: | diameter: | spectrum | | | | | (relative | Plating |
| | 5-100 μm | 1-5 μm | 1-100 μm | D1/PH | D2/PH | Rq | Thickness | Df | value) | adhesion |
| | — | — | — | — | — | μm | mm | — | — | — |
| Example | | | | | | 0.3 | 0.15 | 7.0 × 10⁻⁵ | | |
| 1 | | | | | | | | | | |
| Example | | | | | | 0.2 | 0.08 | 7.0 × 10⁻⁵ | | A |
| 2 | | | | | | | | | | |
| Example | 1200 | 14900 | 16100 | 0.58 | 0.19 | 0.12 | 0.23 | 7.0 × 10⁻⁵ | | |
| 3 | | | | | | | | | | |
| Example | 3500 | 91000 | 94500 | 0.57 | 0.19 | 0.15 | 0.17 | 7.0 × 10⁻⁵ | 1.35 | A |
| 4 | | | | | | | | | | |
| Example | 170 | 2600 | 2770 | 0.58 | 0.19 | 0.07 | 0.25 | 7.0 × 10⁻⁵ | | A |
| 5 | | | | | | | | | | |
| Example | 1100 | 5300 | 6400 | 0.56 | 0.17 | 0.15 | 0.2 | 7.0 × 10⁻⁵ | 1.066 | |
| 6 | | | | | | | | | | |
| Example | | | | | | 0.05 | 0.2 | 3.0 × 10⁻⁴ | | A |
| 7 | | | | | | | | | | |
| Example | | | | | | 0.09 | 0.05 | 3.0 × 10⁻⁴ | >1.4 | A |
| 8 | | | | | | | | | | |
| Example | | | | | | 0.03 | 0.15 | | | A |
| 9 | | | | | | | | | | |
| Example | | | | | | 0.03 | 0.15 | | | A |
| 10 | | | | | | | | | | |
| Example | | | | | | 0.02 | 0.2 | | >1.4 | A |
| 11 | | | | | | | | | | |
| Example | | | | | | 0.04 | 0.2 | | >1.4 | A |
| 12 | | | | | | | | | | |
| Example | | | | | | 0.08 | 0.2 | | >1.4 | A |
| 13 | | | | | | | | | | |
| Example | | | | | | 0.0001 | 0.4 | 7.0 × 10⁻⁵ | 1 | B |
| 14 | | | | | | | | | | |

As shown in Table 1, in Examples 1 to 13, since the root mean square height Rq on the substrate surface was 1 nm or more and 300 nm or less, a result was obtained that the adhesion to metal plating was high. Since the dielectric loss is very small and the thickness of the substrate is small, a reduction in high-frequency transmission loss can be realized. 5 On the other hand, the synthetic quartz glass substrate in Example 14 (AQ, manufactured by AGC Inc.) had an Rq of 0.0001 μm, and as a result of the plating adhesion test, peeling of the plating was visually observed.

Although the present invention has been described in detail with reference to specific embodiments, it is apparent to those skilled in the art that various changes and modifications can be made without departing from the spirit and scope of the present invention. The present application is based on a Japanese Patent Application No. 2023-214759 filed on Dec. 20, 2023, the content of which is incorporated herein by reference.

### REFERENCE SIGNS LIST

10 silica glass substrate
20 metallized layer
100 metallized substrate

What is claimed is:

1. A silica glass substrate having a root mean square height Rq of 1 nm or more and 300 nm or less on a substrate surface, and a thickness of 10 μm or more and 2 mm or less.

2. The silica glass substrate according to claim 1, wherein the number of defects having an average diameter of 1 μm or more and 100 μm or less is 500,000 or less per cm².

3. The silica glass substrate according to claim 1, wherein an H₂O concentration converted from β-OH is less than 100 ppm by mass.

4. The silica glass substrate according to claim 1, wherein a total content of Na, K, and Ca is 0.1 ppm by mass or more and 50 ppm by mass or less.

5. The silica glass substrate according to claim 1, wherein a content of C is 5 ppm by mass or less.

6. The silica glass substrate according to claim 1, wherein a content of Zr is 50 ppm by mass or less.

7. The silica glass substrate according to claim 1, wherein a content of Ti is 50 ppm by mass or less.

8. The silica glass substrate according to claim 1, wherein a content of Al is 50 ppm by mass or less.

9. The silica glass substrate according to claim 1, wherein a ratio (D2/PH) of an intensity (D2) to a height (PH) of a peak derived from a three-membered ring structure in a Raman spectrum is 0.10 or more.

10. The silica glass substrate according to claim 1, wherein a ratio (D1/PH) of an intensity (D1) to a height (PH) of a peak derived from a four-membered ring structure in a Raman spectrum is 0.40 or more.

11. The silica glass substrate according to claim 1, which is used in a high-frequency device.

12. A metallized substrate comprising the silica glass substrate according to claim 1 and a metallized layer provided on a surface of the silica glass substrate.

13. A glass substrate having a root mean square height Rq of 1 nm or more and 300 nm or less on a substrate surface, and a thickness of 10 μm or more and 2 mm or less, wherein the glass substrate comprises 60 mol % or more and less than 100 mol % of SiO₂ as represented by mol % based on oxides.

14. The glass substrate according to claim 13, further comprising 10 mol % or more and 35 mol % or less of B₂O₃ as represented by mol % based on oxides.

15. The glass substrate according to claim 13, further comprising at least one of P₂O₅, GeO₂, CaO, MgO, BaO, Li₂O, Na₂O, K₂O, SnO₂, ZnO, and TiO₂ as represented by mol % based on oxides, wherein a total content thereof is 1 mol % or more and 15 mol % or less.

16. The glass substrate according to claim 13, wherein a total content of Na, K, and Ca is 0.1 ppm by mass or more and 50 ppm by mass or less.

17. The glass substrate according to claim 13, wherein a content of C is 5 ppm by mass or less.

18. The glass substrate according to claim 13, wherein a content of Zr is 50 ppm by mass or less.

19. The glass substrate according to claim 13, wherein a content of Ti is 50 ppm by mass or less.

20. The glass substrate according to claim 13, wherein a content of Al is 50 ppm by mass or less.

21. The glass substrate according to claim 13, which is used in a high-frequency device.

22. A metallized substrate comprising the glass substrate according to claim 13 and a metallized layer provided on a surface of the glass substrate.
